(19) United States
(12) Patent Application Publication
(10) Pub. No.: US 2025/0392144 A1
(43) Pub. Date: Dec. 25, 2025

(54) BATTERY SYSTEM AND BATTERY PACK CONNECTION STATE IDENTIFICATION METHOD

(71) Applicant: RENOGY NEW ENERGY CO., LTD., Suzhou, Jiangsu (CN)

(72) Inventors: Haiju SHI, Suzhou, Jiangsu (CN); Chengcheng HUANG, Suzhou, Jiangsu (CN)

(21) Appl. No.: 19/105,726

(22) PCT Filed: Mar. 30, 2023
(86) PCT No.: PCT/CN2023/085153

§ 371 Date: Feb. 21, 2025

(30) Foreign Application Priority Data
Aug. 22, 2022 (CN) 202211004551.6

(51) Int. Cl. H02J 7/00; H01M 10/42; H01M 50/569

(52) U.S. Cl. CPC H02J 7/0036; H01M 10/425; H01M 50/569; H02J 7/00041; H02J 7/0013; H02J 7/0048; H01M 2010/4271

(57) ABSTRACT

The present disclosure relates to a battery system and a battery pack connection state identification method. The battery system includes a plurality of battery packs being directly or indirectly connected; a signal line being in controllable connection with each of the plurality of battery packs; and a detection and determination module configured to acquire a voltage value of the signal line, and determine, according to the voltage value, at least one selected from a group consisting of a connection mode between the plurality of battery packs and a relative position between the plurality of battery packs.

### CROSS REFERENCE TO RELATED APPLICATIONS

The present application is a National Stage of International Application No. PCT/CN2023/085153, filed on Mar. 30, 2023, which claims priority to Chinese patent application No. 202211004551.6, filed on Aug. 22, 2022, and entitled “BATTERY SYSTEM AND BATTERY PACK CONNECTION STATE IDENTIFICATION METHOD”, the entire contents of which are hereby incorporated by reference.

### TECHNICAL FIELD

The present disclosure relates to the technical field of new energy, and in particular, to a battery system and a battery pack connection state identification method.

### BACKGROUND

With the development of renewable energy technology, the application scope of the battery becomes wider and wider. Recently, many manufacturers manufacture battery packs for production and sales. After purchasing the battery packs, a user may connect the battery packs in series or in parrel to meet the requirements of a power consumption system for the battery capacity and output voltage.

Generally speaking, when the user connects the battery packs in series or in parallel, it is necessary to ensure that the total capacity, the remaining capacity, and the voltage across two poles of each battery pack are completely consistent. Then, several battery packs are selected to be connected in parallel to form a battery pack string. Finally, a plurality of battery pack strings are connected in series to obtain a battery system composed of a plurality of battery packs and having the user's required rated capacity and voltage.

However, in an actual application process, it cannot be guaranteed that every user reads the operation guide and performs processing according to the operation guide, and it also cannot be guaranteed that every user has a certain basic theoretical knowledge of electrical engineering and a necessary electrical tool. Generally, the user may randomly connect the battery packs in series or in parallel. If the connection between the battery packs is unreasonable or an error occurs, a risk that the battery pack cannot be powered on correctly may be caused and even a potential safety hazard may be generated, thereby seriously affecting the power consumption experience of the user.

Therefore, it is necessary to propose a method that can automatically identify the connection state of each battery pack after the battery packs are connected in series, in parallel, or in series and parallel.

### SUMMARY

In view of this, regarding the above-mentioned technical problems, it is necessary to provide a battery system and a battery pack connection state identification method that can automatically identify a connection state of each battery pack after battery packs are connected.

For this purpose, as a first aspect of the present disclosure, a battery system is provided, which includes:
a plurality of battery packs, the plurality of battery packs being directly or indirectly connected;
a signal line, the signal line being in controllable connection with each of the battery packs; and
a detection and determination module, configured to acquire a voltage value of the signal line, and determine, according to the voltage value, at least one selected from a group consisting of a connection mode and a relative position among the plurality of battery packs.

According to another aspect of the present disclosure, a battery pack connection state identification method is further provided, the method is applied to a first battery pack in a battery system including at least one first battery pack and at least one second battery pack, and the method includes:
controlling the first battery pack and the second battery pack to connect a signal line;
acquiring a voltage value of the signal line; and
determining, according to the voltage value, a connection state between the first battery pack and the second battery pack.

The details of one or more embodiments of the present disclosure are presented in the accompanying drawings and descriptions below. Other features, objectives, and advantages of the present disclosure will become apparent from this specification, the accompanying drawings, and the claims.

### BRIEF DESCRIPTION OF DRAWINGS

To describe the technical solutions in the embodiments of the present disclosure or the conventional technology more clearly, the drawings used in the embodiments or the conventional technology will be briefly described below. Obviously, the drawings in the following descriptions are merely embodiments of the present disclosure. For those skilled in the art, other drawings can be obtained from the drawings of the present disclosure without creative work.

FIG. 1 is a structural schematic diagram of a battery pack in an embodiment;

FIG. 2 is a structural schematic diagram of a control module in an embodiment;

FIG. 3 is a structural schematic diagram of a first voltage access module and a second voltage access module in an embodiment;

FIG. 4 is a structural schematic diagram of a voltage dividing circuit, a first voltage access module, and a second voltage access module in an embodiment;

FIG. 5 is another structural schematic diagram of a voltage dividing circuit, a first voltage access module, and a second voltage access module in an embodiment;

FIG. 6 is a structural schematic diagram of a voltage measuring circuit of a detection and determination module in an embodiment;

FIG. 7 is a structural schematic diagram of a battery system in an embodiment;

FIG. 8 is a specific structural schematic diagram of a battery system in an embodiment;

FIG. 9 is a structural schematic diagram of a battery pack in another embodiment;

FIG. 10 is a structural schematic diagram of a voltage access module and a voltage sampling module of a battery pack in another embodiment;

FIG. 11 is a structural schematic diagram of a battery system in another embodiment;

FIG. 12 is a schematic flowchart of a battery pack connection state identification method in an embodiment;

FIG. 13 is a schematic flowchart of a battery pack connection state identification method in another embodiment;

FIG. 14 is a schematic flowchart of steps for determining a control host in an embodiment;

FIG. 15 is a schematic flowchart of measuring a voltage value of a signal line in an embodiment;

FIG. 16 is a schematic flowchart of measuring a voltage value of a signal line in another embodiment;

FIG. 17 is a schematic flowchart of determining a connection state between a first battery pack and a second battery pack in an embodiment;

FIG. 18 is a schematic flowchart of steps for determining a battery pack connection state in an embodiment;

FIG. 19 is a structural schematic diagram of a relative position between a first battery pack and a second battery pack, a first voltage access module, and a second voltage access module in an embodiment;

FIG. 20 is a structural schematic diagram of a relative position between a first battery pack and a second battery pack, a first voltage access module, and a second voltage access module in an embodiment;

FIG. 21 is a structural schematic diagram of a relative position between the first battery pack and the second battery pack, a voltage access module, and a voltage sampling module in an embodiment;

FIG. 22 is a structural schematic diagram of a relative position between a first battery pack and a second battery pack, a voltage access module, and a voltage sampling module in an embodiment;

FIG. 23 is a schematic flowchart of steps for determining a battery pack connection state;

FIG. 24 is a structural schematic diagram of a relative position between a first battery pack and a second battery pack, a first voltage access module, and a second voltage access module in an embodiment;

FIG. 25 is a structural schematic diagram of a relative position between a first battery pack and a second battery pack, a first voltage access module, and a second voltage access module in an embodiment;

FIG. 26 is a structural schematic diagram of a relative position between a first battery pack and a second battery pack, a voltage access module, and a voltage sampling module in an embodiment;

FIG. 27 is a structural schematic diagram of a relative position between a first battery pack and a second battery pack, a voltage access module, and a voltage sampling module in an embodiment;

FIG. 28 is a schematic flowchart of steps for determining a battery pack connection state;

FIG. 29 is a structural schematic diagram of a relative position between a first battery pack and a second battery pack, a voltage access module, and a voltage sampling module in an embodiment;

FIG. 30 is a structural schematic diagram of a relative position between a first battery pack and a second battery pack, a voltage access module, and a voltage sampling module in an embodiment;

FIG. 31 is a schematic flowchart of steps for determining a battery pack connection state;

FIG. 32 is a structural schematic diagram of a relative position between a first battery pack and a second battery pack, a voltage access module, and a voltage sampling module in an embodiment;

FIG. 33 is a structural schematic diagram of a relative position between a first battery pack and a second battery pack, a voltage access module, and a voltage sampling module in an embodiment; and

FIG. 34 is a schematic diagram of a connection structure of a plurality battery packs in a hybrid connection in an embodiment.

Reference numerals of components in the drawings are as follows: 100, battery pack; 120, battery set; 140, first voltage access module; 160, second voltage access module; 180, control module; 182, BMS; 184, voltage measuring circuit; 142, first switch; 144, first resistor; 162, second switch; 164, second resistor; 220, detection and determination module; 320, battery set; 340, voltage access module; 360, voltage sampling module; 380, detection and determination module.

### DETAILED DESCRIPTION

The technical solutions in the embodiments of the present disclosure will be clearly and completely described below combing with the drawings in the embodiments of the present disclosure, and apparently, the described embodiments are only a part of the embodiments of the present disclosure and not all the embodiments. Based on the embodiments of the present disclosure, all other embodiments obtained by those skilled in the art without creative work fall within the protection scope of the present disclosure.

Unless otherwise defined, all technical and scientific terms used in the present disclosure have the same meaning as commonly understood by those skilled in the art in the technical field to which the present disclosure belongs. The terms used in the description of the present disclosure are only for the purpose of describing specific embodiments and are not intended to limit the present disclosure.

It should be noted that “include”, “comprise”, or any other variants thereof in this specification are intended to cover a non-exclusive inclusion, such that a process, method, object, or apparatus including a set of elements include not only those elements, but also other elements that are not expressly listed or elements that are inherent to such a process, method, object, or apparatus. Without more limitations, elements defined by the sentence “comprise a . . . ” does not exclude that there are still other same elements in the process, method, object, or apparatus including the element. It should be further understood that, as used herein, the singular forms “a”, “an”, and “the” are intended to also include the plural form, unless the context indicates otherwise. Furthermore, the terms “or”, “and/or”, “comprises at least one of the following” used herein can be interpreted as inclusive or imply any one or any combination thereof. Exceptions to the definition only occur when combinations of elements, functions, steps, or operations are inherently mutually exclusive in a certain way.

It should be understood that, although the terms “first”, “second”, “third”, etc. may be used herein to describe various parameters or modules, however these parameters or modules should not be limited to these terms. These terms are only used to distinguish parameters or modules of the same type from each other. For example, without departing from the scope of the present disclosure, a “first” parameter can also be referred to as a “second” parameter, and similarly, a “second” parameter can also be referred to as a “first” parameter. Depending on the context, the words “in a case that” and “if” used herein can be interpreted as “when” or “while” or “in response to determining” or “in response to measuring”. Similarly, depending on the context, phrases such as “in a case of determining” or “in a case of measuring (a stated condition or event)” can be interpreted as “when determining” or “in response to determining” or “when measuring (a stated condition or event)” or “in response to measuring (a stated condition or event”. In addition, components, features, and elements with the same name in different embodiments of the present disclosure may have the same meaning or different meanings, and the specific meaning needs to be determined according to the explanation in a specific embodiment or further in combination with the context of the specific embodiment.

It should be understood that although the various steps in a flowchart of an embodiment of the present disclosure are shown in sequence as indicated by an arrow, these steps are not necessarily executed in the order indicated by the arrow. Unless otherwise specifically described in the present disclosure, the execution order of these steps are not strictly limited, which can be executed in other orders. Moreover, at least part of the steps in the drawings may include a plurality of sub-steps or a plurality of stages, and these sub-steps or stages are not necessarily executed at the same time and can be executed at different times. These sub-steps or stages are not necessarily executed in order, but may be executed in turn or alternately with other steps or at least a part of sub-steps or stages of other steps.

It should be understood that the specific embodiments described herein are only for illustrating the present disclosure and are not intended to limit the present disclosure.

A battery system provided in the present disclosure is suitable for various application scenarios, such as the fields of grid-connected power generation and energy storage, off-grid photovoltaic energy storage (configured to supply power to an electric device in a family, a recreational vehicle, or a marine), wind storage power generation, an electrical-powered device, etc., which can be specifically determined according to a practical application scenario and is not limited herein.

The off-grid photovoltaic energy storage field will be taken as an example to describe below. Other application scenarios are basically similar and will not be repeated.

In the off-grid photovoltaic energy storage application scenario, a complete photovoltaic energy storage system at least includes a photovoltaic power generation system, a power conversion system, a battery system, and a power consumption system. The photovoltaic power generation system is composed of a plurality of solar cell panels connected in series and parallel and configured to convert solar energy into electric energy. The power conversion system injects the electric energy generated by the photovoltaic power generation system into the battery system for storage. The power consumption system adapts the stored electric energy in the battery system to the electric power needed by the electric device. The above-mentioned power conversion system can usually be implemented by, for example, a DC/DC converter with an MPPT function, the power consumption system can usually be implemented by a DC/DC converter or a DC/AC converter. The battery system is mainly described here. The battery system is usually composed of a plurality of battery packs connected with each other. The connection in series of the battery packs can improve the output voltage of battery sets, and the connection in parallel of the battery packs can obtain a larger battery capacity. Therefore, to obtain a battery system with a target voltage level and capacity, a user may connect a plurality of battery packs in series and parallel with each other so as to obtain a battery system with a relatively high voltage and a relatively large capacity for energy storage and power supply. At present, some users often randomly connect the battery packs in series and/or in parallel after obtaining them, or may make mistakes in the process of connecting the battery packs in series or in parallel, thereby resulting in a connection error. After the battery pack is powered on, the battery system fails to identify a connection relationship of all the battery packs, thereby making it difficult to manage charging or discharging of each battery pack well and affecting the normal use of the battery system. In a serious case, potential safety hazard to the battery pack may arise.

To solve the aforementioned problems, the present disclosure provides a battery system and a battery pack connection state identification method that can automatically identify a connection state of each battery pack after the battery packs are connected in series and in parallel.

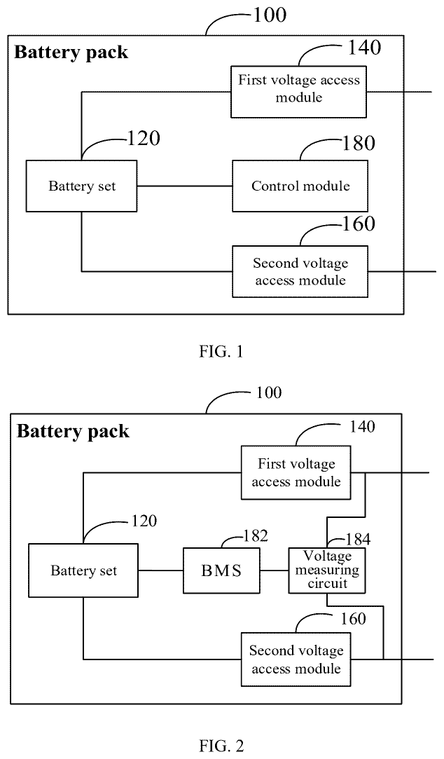

In an embodiment, please refer to FIG. 1, the present disclosure provides a battery pack 100 including a battery set 120, a first voltage access module 140, a second voltage access module 160, and a control module 180.

The battery set 120 is connected with the first voltage access module 140, the second voltage access module 160, and the control module 180, respectively.

Optionally, the battery set 120 is composed of several battery cells connected in series and/or parallel to each other and used for energy storage and power supply. The number of the battery cells is greater than or equal to 1, and a specific number can be determined according to an actual application scenario, which is not limited herein. A type of the battery cell may include but not limited to a lithium cobalt oxide battery, a lithium nickel cobalt manganese oxide battery, a lithium nickel cobalt aluminum oxide battery, a lithium iron phosphate battery, or a lithium cobalt oxide battery. The first voltage access module 140 and the second voltage access module 160 are configured to controllably connect a positive terminal and a negative terminal of the battery set 120 to a first signal line (not shown in the figure) and a second signal line (not shown in the figure), respectively, which will be specifically described in a subsequent embodiment. The control module 180 is configured to detect a performance parameter of the battery set 120.

In some feasible implementations, as shown in FIG. 2, the control module 180 may include a detection and determination module, and the detection and determination module may include a battery management system (BMS) 182 and a voltage measuring circuit 184. The BMS 182 is connected with the battery set 120 and the voltage measuring circuit 184, respectively. The BMS 182 is configured to intelligently manage and maintain various battery packs 100, monitor a state of the battery pack 100, prevent overcharging and over discharging of the battery pack 100, thereby extending the service life of the battery pack 100. Specifically, the BMS 182 can achieve one or more of the following functions: measurement or monitoring of a cell parameter of a single battery cell in the battery set 120, which includes one or more cell parameters as follows, such as a cell voltage, a cell State of Charge (i.e., SOC), a cell temperature, a cell current, and a cell State of Health (i.e., SOH); energy balance of a single battery cell in the battery set 120, that is, the signal battery cell is performed balanced charging and discharging to cause the battery set 120 to achieve a balanced and consistent state; measurement of a total voltage of the battery set 120; measurement of a total current, calculation of the SOC of the battery set 120, and accurate estimation of a state-of-charge of the battery set 120 (i.e., the SOC of the battery) to ensure that the SOC is maintained within a reasonable range and prevent damage to the battery caused by overcharging or over discharging; dynamically monitoring a working state of the battery set 120: collecting a voltage and a temperature of the battery set 120 in real time during a charging and discharging process of the battery, and collect a charging and discharging current and a total voltage to prevent an overcharging or over discharging phenomenon of the battery, and displaying real-time data; data recording and analysis and selecting a defective battery at the same time to keep the operation reliability and efficiency of the battery; and a communication networking function.

The voltage measuring circuit 184 is connected with an output end of the first voltage access module 140 and an output end of the second voltage access module 160, respectively, and is configured to measure a voltage between the output end of the first voltage access module 140 and the output end of the second voltage access module 160. When the output end of the first voltage access module 140 is connected with the first signal line (not shown in the figure) and the output end of the second voltage access module 160 is connected with the second signal line (not shown in the figure), a voltage value measured by the voltage measuring circuit 184 is equal to a voltage between the first signal line and the second signal line. In an actual working process, the voltage measuring circuit 184 is configured to collect the voltage between the first signal line and the second signal line. After obtaining the voltage, the BMS 182 performs corresponding determination and control, which will be described in detail in a subsequent embodiment of the present disclosure.

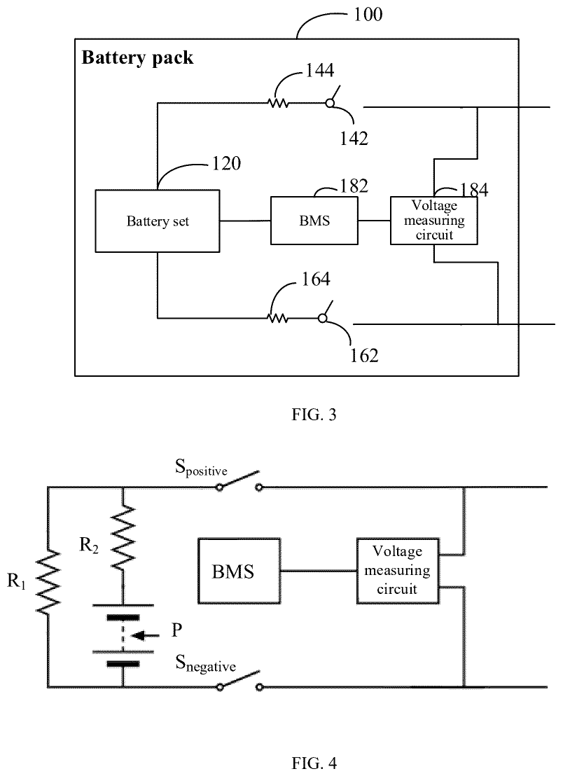

In some feasible implementations, as shown in FIG. 3, the first voltage access module 140 at least includes a first switch, and the second voltage access module 160 at least includes a second switch.

Optionally, the first voltage access module 140 can be directly as the first switch, and the second voltage access module 160 can be directly as the second switch, that is, two terminals of the battery set 120 can be directly connected with the first signal line (not shown in the figure) and the second signal line (not shown in the figure) through the first switch and the second switch, respectively.

Optionally, the first voltage access module 140 may also include a first switch 142 and a first resistor 144. The battery set 120 may connect with the first switch 142 after connecting with the first resistor 144, or the battery set 120 may also connect with the first resistor 144 after connecting with the first switch 142. The second voltage access module 160 may also include a second switch 162 and a second resistor 164. The battery set 120 may connect with the second switch 162 after connecting with the second resistor 164, or the battery set 120 may also connect with the second resistor 164 after connecting with the second switch 162. The number of the first switch 142 and the second switch 162 are not limited in this embodiment, as long as the purpose of controllably connecting two terminals of the battery set 120 to the first signal line (not shown in the figure) and the second signal line (not shown in the figure) can be achieved. The first switch 142 and the second switch 162 can be implemented using a metal oxide semiconductor field effect transistor (also referred to as MOSFET or MOS transistors for short), or an electronic component such as a transistor and a relay, which is not limited herein as long as the purpose of performing connecting and disconnecting according to a corresponding driving signal to enable controllable connection between the battery set and the signal line can be achieved.

In this implementation, the first resistor 144 and the second resistor 164 can reduce an overlarge current when the battery pack is connected with the signal line, that is to say, the first resistor 144 and the second resistor 164 can be replaced by a first current limiting element and a second current limiting element, respectively. The number, a connection mode, and an element type of the current limiting element are not limited as long as the purpose of reducing a current can be achieved when the battery set 120 is connected with the signal line. The implementation manners are all within the protection scope of the present disclosure.

In some feasible implementations, the battery pack may also include a voltage dividing module connected with the battery set 120. The voltage dividing module is configured to divide an output voltage of the battery set 120, so that when the battery set 120 is connected with the signal line, the voltage dividing module can reduce an amplitude of an output current of the battery set 120, thereby avoiding damage or impact on the voltage measuring circuit 184.

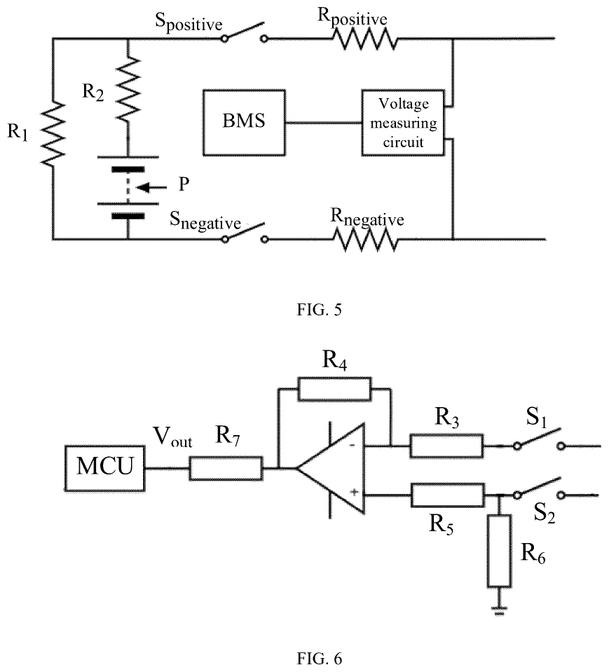

Optionally, the positive terminal of the battery set 120 is connected with a first input module through the voltage dividing module, and the negative terminal of the battery set 120 is directly connected with a second input module. The voltage dividing module may include resistors connected in parallel or series. FIG. 4 and FIG. 5 illustrate a feasible implementation of a battery pack including a voltage dividing module, where P may be the aforementioned battery set 120. As shown in FIG. 4, a first voltage access module 140 includes a first switch Sₚₒₛᵢₜᵢᵥₑ, the second voltage access module 160 includes a second switch S_{negative}, and a resistor R1 and a resistor R2 are connected in series to form the voltage dividing module in this implementation. In this implementation, a voltage measured by the voltage measuring circuit 184 is a voltage across two ends of the voltage dividing resistor R1, not a voltage across two ends of the battery set P. Therefore, a circuit overhead of the voltage measuring circuit can be reduced and a risk of circuit damage caused by a high current can be avoided when the voltage measuring circuit is directly connected with the battery set P. As an optional implementation, on the basis of the implementation of the battery pack shown in FIG. 4, the voltage access module may further include a resistor, as shown in FIG. 5, the first voltage access module 140 includes a first switch Sₚₒₛᵢₜᵢᵥₑ and a resistor Rₚₒₛᵢₜᵢᵥₑ, and the second voltage access module 160 includes a second switch S_{negative} and a resistor R_{negative}. The resistor Rₚₒₛᵢₜᵢᵥₑ and the resistor R_{negative} can further reduce the amplitude of the current in the whole circuit.

In this embodiment, the battery set 120 is connected with the signal line through the voltage dividing module. A reason for dividing the voltage is that if a voltage of a single battery pack is relatively high, or if a system voltage is too high when a plurality of battery packs are connected in series and used, it may cause the voltage measuring circuit 184 to bear an overlarge pressure, thereby resulting in damage to the voltage measuring circuit 184.

In an embodiment, the detection and determination module as described above includes the BMS 182 and the voltage measuring circuit 184, and the voltage measuring circuit at least includes an operational amplifier configured to acquire a voltage value between the first signal line and the second signal line. A microcontroller unit (MCU) of the BMS is configured to determine, according to the voltage value, a connection mode between the plurality of battery packs and/or a relative position between the plurality of battery packs.

Specifically, as shown in FIG. 6 which is a structural schematic diagram of a voltage measuring circuit of a detection and determination module, an MCU can be an MCU in the BMS of the battery pack. A first input end (an inverting input end) of the operational amplifier is connected with a resistor R3, and the resistor R3 is connected with a switch S1. The switch S1 can be connected with any one of the first signal line and the second signal line, as well as an output end of the first voltage access module 140. A second input end (a non-inverting input end) of the operational amplifier is connected with a balancing resistor R5, and the balancing resistor R5 is respectively connected with a switch S2 and a pull-down resistor R6. The switch S2 is connected with the other one of the first signal line and the second signal line, as well as an output end of the second voltage access module 160. As a preferred implementation, the first input end of the operational amplifier is in controllable connection with the first signal line through the resistor R3 and the first switch S1, and the second input end is in controllable connection with the second switch S2 through the balancing resistor R5. The pull-down resistor R6 is connected to the ground. An output end of the operational amplifier is connected with the MCU through a resistor R7, and configured to output a value Vₒᵤₜ representing a voltage difference value between the first signal line and the second signal line measured by the voltage measuring circuit to the MCU. After obtaining the value Vₒᵤₜ, the MCU can determine, according to the voltage value, a connection mode between the plurality of battery packs and/or a relative position between the plurality of battery packs. A specific determination method will be described in detail in subsequent embodiments and will not be repeated here. The detection and determination module also includes a feedback resistor R4, and one end of the feedback resistor R4 is connected with the first input end of the operational amplifier, and the other end is connected with the output end of the operational amplifier.

For the battery packs as described above, when the plurality of battery packs are connected with each other, by connecting a battery set of each battery pack to the signal line via the voltage access module and measuring the voltage value of the signal line, the connection mode of each battery pack and/or a relative position of each battery pack can be determined, thus facilitating performing charging and discharging management on each battery pack in the battery system by the battery system.

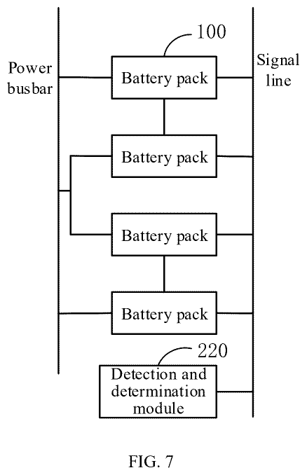

In another embodiment of the present disclosure, please refer to FIG. 7, the present disclosure further provides a battery system, and the battery system includes a plurality of battery packs 100, a signal line, and a detection and determination module 220. The plurality of battery packs 100 are directly or indirectly connected. The signal line is in controllable connection with each battery pack 100. The detection and determination module is configured to acquire a voltage value of the signal line, and determine a connection mode between the plurality of battery packs according to the voltage value, and also determine a relative position between the plurality of battery packs according to the voltage value.

In some implementations, the plurality of battery packs 100 can be directly or indirectly connected with each other in series or in parallel and/or in series. Specifically, a connection mode between the plurality of battery packs 100 may be a series connection, a parallel connection, a series connection first and then a parallel connection, and a parallel connection first then a parallel connection, and the specific connection mode is not limited in this implementation, and a user can set the connection mode between the plurality of battery packs according to an actual application scenario and the power requirement. In a typical application scenario, the user expands the capacity of an original battery system. Generally speaking, as the increase of battery usage time, the increase of the number of electrical devices or the power, and other factors, the original battery system will no longer be able to meet the power requirement. In this case, the user may purchase new battery packs to expand the capacity of the original battery system. However, it can't be guaranteed that every user reads the operation guide and performs processing according to the operation guide, and it can't be guaranteed that every user has certain basic theoretical knowledge of electrical engineering and a necessary electric tool, an unreasonable or incorrect connection of battery packs may be occurred during the capacity expanding process. For example, battery packs that should be connected in series are connected in parallel, battery packs that should be connected in parallel are connected in series, and the number of battery packs in each battery pack set connected in parallel in a hybrid system is different.

In some implementations, the plurality of battery packs 100 can be in communication connection, for example, an RS485 or a CAN communication chip is built in each battery pack 100, and the battery packs are connected with each other through the RS485 or the CAN communication bus to form the communication connection.

In some implementations, the battery system may also include a power busbar, and the power busbar is configured to connect the battery system with a load, a power conversion module, or a power grid. The battery system is charged or discharged using the load, the power conversion module, or the power grid.

In some implementations, the signal line is in controllable connection with each battery pack 100. An implementation mode of the controllable connection usually refers to that connection and disconnection of a circuit of each battery pack 100 connected with the signal line are controllable. When the battery pack 100 receives a first type signal, the battery pack 100 is connected with the signal line. When the battery pack 100 receives a second type signal, the battery pack 100 is disconnected with the signal line. Therefore, a controllable connection between each battery pack 100 and the signal line can be achieved. When the battery pack 100 is connected with the signal line, an output voltage of the battery pack 100 can be loaded onto the signal line and thus be detected by the detection and determination module 220.

The detection and determination module 220 is configured to acquire a voltage value of the signal line, execute a corresponding determination strategy according to the voltage value, and then determine a connection mode between the plurality of battery packs and a relative position relationship of the plurality of battery packs.

In some implementations, since each battery pack 100 is in controllable connection with the signal line, different battery packs 100 can be sequentially controlled to connect with the signal line, thereby acquiring a corresponding voltage value of the signal line.

In some implementations, the battery pack includes a battery set 120, a first voltage access module 140, and a second voltage access module 160. The signal line includes at least one first signal line and at least one second signal line. A positive terminal of the battery set 120 is in controllable connection with the first signal line via the first voltage access module 140, and a negative terminal of the battery set 120 is in controllable connection with the second signal line via the second voltage access module 160. The first voltage access module 140 includes at least one first switch 142, and the second voltage access module 160 includes at least one second switch 162.

In some other implementations, a connection mode between the positive and negative terminals of the battery set 120 and the voltage access module can be exchanged. For example, the negative terminal of the battery set 120 is in controllable connection with the first signal line via the first voltage access module 140, and the positive terminal of the battery set 120 is in controllable connection with the second signal line via the second voltage access module 160. The first voltage access module 140 includes at least one first switch 142, and the second voltage access module 160 includes at least one second switch 162. The first switch 142 and the second switch 162 can be turned on or off according to a control signal, so that both terminals (the positive terminal and the negative terminal) of the battery set 120 are connected or disconnected with the first signal line and the second signal line.

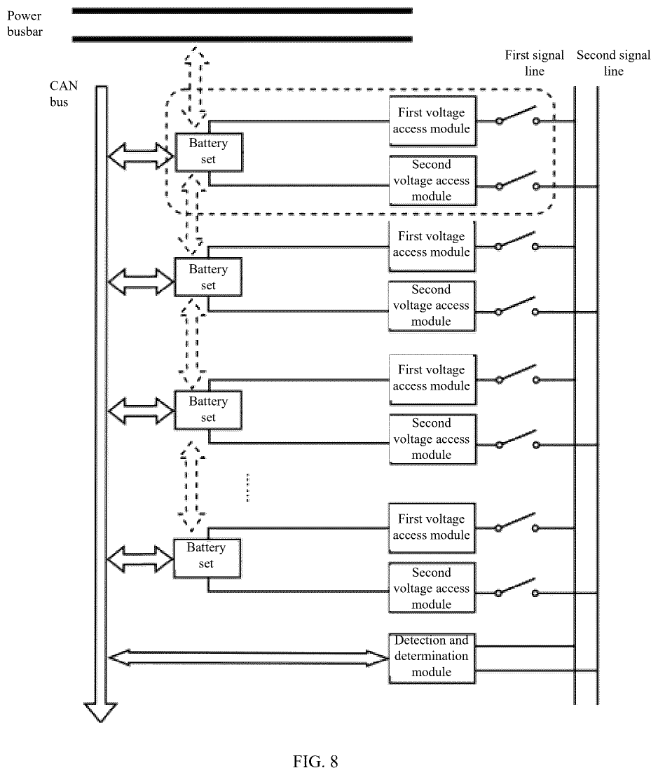

Optionally, as shown in FIG. 8, communication connection can be established between the battery packs 100 and between the battery packs 100 and the detection and determination module 220, e.g., via the RS485 or the CAN communication bus. It can be understood that the battery packs 100 as well as the battery packs 100 and the detection and determination module 220 can be in communication connection via other wired or wireless modes. In this embodiment, specific communication modes between the battery packs and between the battery pack and the detection and determination module 220 are not limited in this embodiment. Through the communication connection, a plurality of functions such as host competition, address allocation, control signal transmission, and operation data transmission can be performed between the battery packs 100 and between the battery pack 100 and the detection and determination module 220.

In the embodiment as shown in FIG. 8, the detection and determination module 220 is disposed as an independent module in a power system. In a specific implementation, the independent module can be a control box with a display screen. The control box can be independent from the plurality of battery packs, can be installed and controlled separately, and provided with a wiring port configured to connect with the first signal line and the second signal line. The display screen can be configured to display an acquired voltage value of the signal line, a state parameter of the battery system, a state parameter of each battery pack 100 in the battery system, and a connection state of each of the battery packs 100. In addition, a communication connection between the control box and a mobile terminal of a user can be established in a mode such as Bluetooth, Wi-Fi, NFC, etc., so that the user can acquire information about an operating state and an operating parameter of the entire battery system or the battery packs 100 in the battery system through the mobile terminal, and also remotely control the battery system or the battery pack 100 in the battery system at the same time.

In some implementations, the detection and determination module 220 can also be disposed in at least one battery pack 100 in the battery system, and the battery pack 100 can be the battery pack 100 in any one of the implementations shown in FIG. 1 to FIG. 3. In this implementation, the detection and determination module 220 can be connected with the signal line through a voltage access module of the battery pack 100. That is to say, the battery pack 100 can be provided with only two wiring ports, and the wiring ports can be configured to connect with the battery set 120 of the battery pack 100 to the signal line, and to connect with the detection and determination module 220 of the battery pack 100 to the signal line.

In some implementations, the detection and determination module 220 can be disposed in one battery pack 100 of the battery system. In this case, the battery pack 100 provided with the detection and determination module 220 can be served as a control host for the entire battery system, and other battery packs 100 can be served as slaves. The slave can communicate with the control host and be controlled by the control host, thereby reducing the cost and control complexity of the battery system.

In some implementations, the detection and determination module 220 can be disposed in each battery pack 100 of the battery system. In this case, each battery pack 100 needs to compete for a control host through communication connection, and other battery packs 100 serve as slaves to be controlled by the control host. Therefore, when the control host fails, the control host can be switched to other battery packs, thereby ensuring the operation stability of the entire battery system.

In some implementations, each battery pack 100 in the battery system further includes a voltage dividing module connected in series with the battery set. A positive terminal of the battery set is in controllable connection with the first signal line via the voltage dividing module and the first voltage access module, and a negative terminal of the battery set is in controllable connection with the second signal line via the second voltage access module. In some implementations, the positive terminal of the battery set of each battery pack 100 in the battery system is connected with the first input module via the voltage dividing module, and the negative terminal of the battery set is directly connected with the second input module. The voltage dividing module may include resistors connected in parallel or series. FIG. 4 and FIG. 5 illustrate a feasible implementation of a battery pack 100 including a voltage dividing module, where P can be the aforementioned battery set 120. As shown in FIG. 4, the first voltage access module 140 includes a first switch Sₚₒₛᵢₜᵢᵥₑ, the second voltage access module 160 includes a second switch S_{negative}, and resistors R1 and R2 are connected in series and forms the voltage dividing module in this implementation. In this implementation, a voltage measured by the voltage measuring circuit 184 is a voltage across both ends of a voltage dividing resistor R1, not a voltage across both ends of the battery set P, thereby reducing the circuit overhead of the voltage measuring circuit and avoiding the risk of circuit damage caused by a large current when the voltage measuring circuit is directly connected with the battery set P. As an optional implementation, on the basis of the implementation of the battery pack shown in FIG. 4, the voltage access module may further include a resistor, as described in FIG. 5, the first voltage access module 140 includes a first switch Sₚₒₛᵢₜᵢᵥₑ and a resistor Rₚₒₛᵢₜᵢᵥₑ, and the second voltage access module 160 includes a second switch S_{negative} and a resistor R_{negative}. The resistor Rₚₒₛᵢₜᵢᵥₑ and the resistor R_{negative} can further reduce an amplitude of a current in the entire circuit.

In this embodiment, the battery set 120 is connected with the signal line after passing through the voltage dividing module. The reason for dividing a voltage is that if a voltage of a single battery pack 100 is relatively high, or a system voltage is too high when the plurality of battery packs 100 are connected in series and used, it may cause the voltage measuring circuit 184 to bear an overlarge voltage, consequently resulting in damage to the voltage measuring circuit 184.

In some implementations, the detection and determination module 220 at least includes an operational amplifier and an MCU. A first input end of the operational amplifier is connected with the first signal line and a second input end of the operational amplifier is connected with the second signal line to acquire a voltage value between the first signal line and the second signal line. The MCU is configured to determine, according to the voltage value, a connection mode between the plurality of battery packs and determine, according to the voltage value, a relative position between the plurality of battery packs.

A specific implementation mode of the detection and determination module 220 can refer to the above implementation shown in FIG. 6. As shown in FIG. 6, the first input end of the operational amplifier can generally be an inverting input end, and the second input end can generally be a non-inverting input end. As an optional implementation, the first input end of the operational amplifier can also be the non-inverting input end and the second input end can also be the inverting input end.

Further, in the implementation shown in FIG. 6, the first input end of the operational amplifier is in controllable connection with the first signal line through the resistor R3 and the first switch S1, and the second input end is in controllable connection with the second signal line through the balancing resistor R5 and the second switch S2. Thus, the operational amplifier can collect a voltage difference value between the first signal line and the second signal line, and output a sampled value Vₒᵤₜ representing the voltage difference value to the MCU. The MCU can determine the connection mode between the battery packs currently connected with the signal line and/or the relative position between the plurality of battery packs according to the voltage difference value.

Optionally, the voltage value between the first signal line and the second signal line can be directly connected with the operational amplifier through the resistor, or can be further divided proportionally once, and then connected with the operational amplifier to perform subtraction once, and then the voltage values are calculated.

When the voltage value is connected with the operational amplifier to perform subtraction once, an output of a first stage operational amplifier can be boosted from a negative voltage to a positive voltage using a stage operational amplifier, and then proportionally reduced, so that the voltage value can be better measured in this way.

A specific implementation mode of the detection and determination module 220 can refer to a specific structure of the aforementioned voltage measuring circuit 184 shown in FIG. 6. The switch S1 in the detection and determination module 220 is connected with the first signal line. The switch S2 in the detection and determination module 220 is connected with the second signal line. The MCU in the detection and determination module 220 is connected with the communication bus. In addition, a specific connection structure and limitation for the battery pack in this embodiment can refer to the above embodiment of the battery pack, and will not be repeated here.

In an embodiment, the voltage measuring circuit 184 and the BMS 182 in the battery pack as described above constitute the detection and determination module 220 in this embodiment, and specific structures and functions thereof are the same. Therefore, as an optional implementation, the detection and determination module 220 can be disposed in at least one first battery pack of the plurality of battery packs 100, that is, a connection mode between plurality of battery packs and/or a relative position between the plurality of battery packs are determined by the voltage measuring circuit 184 and the BMS 182 in one or more battery packs (the battery pack can be the first battery pack) in the plurality of battery packs 100.

Generally speaking, battery packs in the battery system are adopted battery packs with same rated voltage, and due to balanced control, a battery pack voltage value of each battery pack in the entire battery system is basically the same. That is, even if the voltage values of the battery packs are different, a voltage difference value between any two battery packs is also within a very small range. For example, for a battery pack with a rated voltage of 12 V, the voltage difference value between any two battery packs generally does not exceed 2 V, and even in most cases, does not exceed 1 V. Therefore, the voltage value acquired through the detection and determination module 220 should generally be or be close to an integer multiple of a voltage of a single battery pack, thus the connection mode and/or relative position between the battery packs can be determined.

In some implementations, the detection and determination module 220 may be disposed in at least one first battery pack of the plurality of battery packs 100. The detection and determination module 220 is configured to control a first voltage access module 140 of the first battery pack to connect with the first signal line and communicate with at least one second battery pack of the plurality of battery packs, so that the second battery pack controls a second voltage access module 160 of the second battery pack to connect with the second signal line. The detection and determination module 220 is further configured to acquire a voltage value between the first signal line and the second signal line and determine a connection mode between the first battery pack and the second battery pack according to the voltage value, and/or determine a relative position between the first battery pack and the second battery pack according to the voltage value. The first battery pack can be served as a control host to control other slave battery packs including at least one second battery pack.

Specifically, the detection and determination module 220 is disposed in at least one first battery pack (i.e., the voltage measuring circuit 184 and the BMS 182 in the first battery pack) of the battery system. The detection and determination module 220 controls the first switch 142 in the first voltage access module 140 in the first battery pack to be turned off (conducted), so that a positive terminal of the battery set 120 of the first battery pack is connected with the first signal line via the first voltage access module 140. Further, the detection and determination module 220 further communicates with at least one second battery pack of the plurality of battery packs, so that the second battery pack controls the second switch 162 in the second voltage access module 160 of the second battery pack to be turned off (conducted), and a negative terminal of the battery set 120 of the second battery pack is connected with the second signal line via the second voltage access module 160. Communication with the second battery pack can be achieved in a wired or a wireless mode, and the wired mode can be, for example, connected through a CAN bus or an RS485 bus to perform communication.

The detection and determination module 220 is further configured to acquire a voltage value between the first signal line and the second signal line and determine a connection mode between the first battery pack and the second battery pack and/or a relative position between the first battery pack and the second battery pack according to the voltage value.

Specifically, as described above, after the positive terminal of the first battery pack is connected with the first signal line, and the negative terminal of the second battery pack is connected with the second signal line, the detection and determination module 220 can acquire the voltage value between the first signal line and the second signal line, then execute a corresponding strategy according to the voltage value, and determine the connection mode between the first battery pack and the second battery pack and determine the relative position between the first battery pack and the second battery pack.

Specifically, in this implementation, as a first case, it is assumed that the first battery pack and the second battery pack are connected in parallel, and the detection and determination module 220 is disposed in the first battery pack (i.e., the first battery pack is served as a control host). After the positive terminal of the first battery pack is connected with the first signal line, and the negative terminal of the second battery pack is connected with the second signal line, the voltage value measured by the detection and determination module 220 should be a negative value, and an absolute value of the voltage value is close to a voltage value of the first battery pack (or the second battery pack, since the voltage value of the first battery pack and the voltage value of the second battery pack are basically the same). Thus, a connection relationship between a slave battery pack and the control host battery pack can be determined by controlling the detection and determination module of the control host to acquire the voltage value of the signal line. Further, if the acquired voltage value of the signal line is equal to or close to a negative voltage value of the battery pack, it can be determined that the slave battery pack and the control host battery pack are connected in parallel.

As a second case, it is assumed that the first battery pack and the second battery pack are connected in series, and the detection and determination module 220 is disposed in the first battery pack (i.e., the first battery pack is served as the control host), after the positive terminal of the first battery pack is connected with the first signal line, and the negative terminal of the second battery pack is connected with the second signal line, if the voltage value measured by the detection and determination module 220 is zero or close to zero, it can be determined that the second battery pack is connected in series with the first battery pack, and the negative terminal of the second battery pack is directly connected with the positive terminal of the first battery pack, and no other battery packs and/or battery pack sets are connected in series between the second battery pack and the first battery pack. If the voltage value measured by the detection and determination module 220 is a negative value, and an absolute value of the voltage value is N times or close to N (N is a number greater than or equal to 2) times a voltage of a single battery pack, it can be determined that the second battery pack is connected in series with the first battery pack, the positive terminal of the second battery pack is connected with the negative terminal of the first battery pack, and a total of (N−2) battery packs and/or battery pack sets are further connected in series between the positive terminal of the second battery pack and the negative terminal of the first battery pack. If the voltage value measured by the detection and determination module 220 is a positive value and the voltage value is M times or close to M (M is a number greater than or equal to 1) times a voltage value of a single battery pack, it can be determined that the second battery pack is connected in series with the first battery pack, and the negative terminal of the second battery pack is connected with the positive terminal of the first battery pack, and a total of M battery packs and/or battery pack sets are connected in series between the negative terminal of the second battery pack and the positive terminal of the first battery pack.

Specifically, as described above, after the negative terminal of the first battery pack is connected with the second signal line, and the positive terminal of the second battery pack is connected with the first signal line, the detection and determination module 220 can acquire the voltage value between the first signal line and the second signal line, thereby acquiring the voltage value between the first battery pack and the second battery pack. Then, according to the voltage value between the first battery pack and the second battery pack, a corresponding strategy is executed so as to determine the connection mode between the first battery pack and the second battery pack and/or the relative position between the first battery pack and the second battery pack.

As a further possible implementation, after determining the connection mode between the first battery pack and the second battery pack and/or the relative position between the first battery pack and the second battery pack, the detection and determination module 220 is configured to communicate with the at least one second battery pack, so that the second battery pack controls the first voltage access module 140 of the second battery pack to disconnect with the first signal line. The detection and determination module 220 is further configured to communicate with at least one third battery pack of the plurality of battery packs, so that the third battery pack controls the first voltage access module 140 of the third battery pack to connect with the first signal line. The detection and determination module 220 is further configured to acquire a voltage value between the first signal line and the second signal line and determine the connection mode between the first battery pack and the third battery pack and/or the relative position between the first battery pack and the third battery pack according to the voltage value.

In this implementation, to acquire the connection mode and/or the relative position of each battery pack in the entire battery system, the first battery pack is served as the control host to sequentially detect and determine each slave battery pack. Therefore, after determining the connection mode between the first battery pack and the second battery pack and/or the relative position between the first battery pack and the second battery pack, it is necessary to control the second battery pack to disconnect with the signal line and control the third battery pack to connect with the signal line so as to further determine the connection mode between the first battery pack and the third battery pack and/or the relative position between the first battery pack and the third battery pack. A specific connection mode and relative position determination strategy is completely the same as the above determination strategy of the second battery pack, which is not repeated here.

Repeating the above steps, the first battery pack is served as the control host to control other slave battery packs to connect with the signal line in sequence, and the voltage of the signal line is measured so as to determine the connection mode and/or relative position between each slave battery pack and the first battery pack (control host). Thus, the connection mode and/or the relative position of each battery pack in the entire battery system can be determined.

Optionally, the detection and determination module 220 is not limited to being disposed in the battery pack but can be disposed as an independent module in the battery system. The independent module can be a control box with a display screen. The control box can be independent from the plurality of battery packs, can be installed and controlled separately, and is provided with a wiring port configured to connect with the first signal line and the second signal line. The control box can also communicate with and control the plurality of battery packs in wired or wireless modes. The display screen can be configured to display an acquired voltage value of the signal line, a state parameter of the battery system, a state parameter of each battery pack in the battery system, and a connection state of each battery pack. In addition, a communication connection between the control box and a mobile terminal of a user can be established in a mode such as Bluetooth, Wi-Fi, NFC, etc., so that the user can acquire information about an operating state and an operating parameter of the entire battery system through the mobile terminal, and also remotely control the battery system or the battery pack in the battery system at the same time.

As another possible implementation, the detection and determination module 220 is disposed as an independent module in the battery system, and the detection and determination module 220 is configured to communicate with at least one first battery pack and at least one second battery pack of the plurality of battery packs, so that the first battery pack controls the first voltage access module 140 of the first battery pack to connect with the first signal line and the second battery pack controls the second voltage access module 160 of the second battery pack to connect with the second signal line. The detection and determination module 220 is further configured to acquire the voltage value between the first signal line and the second signal line and determine the connection mode between the first battery pack and the second battery pack and/or the relative position between the first battery pack and the second battery pack according to the voltage value. In this implementation, the detection and determination module 220 is served as the control host to control other slave battery packs including the at least one first battery pack and the at least one second battery pack.

As a further possible implementation, after determining the connection mode between the first battery pack and the second battery pack and/or the relative position between the first battery pack and the second battery pack, the detection and determination module 220 is configured to communicate with the at least one second battery pack, so that the second battery pack controls the second voltage access module 160 of the second battery pack to disconnect with the second signal line. The detection and determination module 220 is further configured to communicate with at least one third battery pack of the plurality of battery packs, so that the third battery pack controls the second voltage access module 160 of the third battery pack to connect with the second signal line. The detection and determination module 220 is further configured to acquire the voltage value between the first signal line and the second signal line and determine, according to the voltage value, the connection mode between the first battery pack and the third battery pack and/or the relative position between the first battery pack and the third battery pack.

Repeating the above steps, the detection and determination module 220 is served as the control host and the first battery pack is served as a reference point, other slave battery packs are controlled to connect with the signal line in sequence, and the voltage of the signal line is measured so as to determine the connection mode and/or the relative position between each slave battery pack and the first battery pack (the reference point), so that the connection mode and/or the relative position of each battery pack in the entire battery system can be determined.

As another possible implementation, the detection and determination module 220 is disposed as an independent module in the battery system, the detection and determination module 220 is configured to communicate with at least one first battery pack and at least one second battery pack of the plurality of battery packs, so that the first battery pack controls the second voltage access module 160 of the first battery pack to connect with the second signal line and the second battery pack controls the first voltage access module 140 of the second battery pack to connect with the first signal line. The detection and determination module 220 is further configured to acquire a voltage value between the first signal line and the second signal line and determine a connection mode between the first battery pack and the second battery pack and/or a relative position between the first battery pack and the second battery pack according to the voltage value. In this implementation, the detection and determination module 220 is served as a control host to control other slave battery packs including the at least one first battery pack and the at least one second battery pack.

As a further possible implementation, after determining the connection mode between the first battery pack and the second battery pack and/or the relative position between the first battery pack and the second battery pack, the detection and determination module 220 is configured to communicate with the at least one second battery pack, so that the second battery pack controls the first voltage access module 140 of the second battery pack to disconnect with the first signal line. The detection and determination module 220 is further configured to communicate with at least one third battery pack of the plurality of battery packs, so that the third battery pack controls the first voltage access module 140 of the third battery pack to connect with the first signal line. The detection and determination module 220 is further configured to acquire the voltage value between the first signal line and the second signal line and determine a connection mode between the first battery pack and the third battery pack and/or a relative position between the first battery pack and the third battery pack according to the voltage value.

Repeating the above steps, the detection and determination module 220 is served as a control host and the first battery back is served as a reference point, other slave battery packs are controlled to connect with the signal line in sequence, and a voltage of the signal line is measured so as to determine a connection mode and/or a relative position between each slave battery pack and the first battery pack (the reference point), so that the connection mode and/or the relative position of each battery pack in the entire battery system can be determined.

It should be noted that in the implementation in which the detection and determination module is disposed as an independent module in the battery system, a determination method how to determine, according to the acquired voltage value between the first signal line and the second signal line, the connection mode and/or the relative position of the battery pack is exactly the same as the determination method in the aforementioned implementation where the detection and determination module is disposed in at least one first battery pack of the plurality of battery packs. For a specific communication mode in this embodiment, please refer to the communication mode with the second battery pack in the aforementioned embodiment, the aforementioned contents will not be repeated here, and other specific implementations can refer to steps in the aforementioned implementation.

It should be further noted that although the voltage value of each battery pack in the battery system is basically the same or similar, a voltage difference also exists and cannot be ignored. Therefore, an absolute value of the voltage value measured by the detection and determination module may not be exactly equal to an integer multiple of a voltage of a single battery pack. To solve this problem, the voltage value measured by the detection and determination module can be divided by the voltage of a single battery pack and rounding is performed to obtain an integer so as to determine a specific multiple (i.e., N times, M times, or zero as mentioned above). For example, for a battery pack with a voltage of 12 V, if the voltage value measured by the detection and determination module is 32.5 V, then 32.5/12˜2.708 is calculated, rounding is performed and 3 times a battery pack voltage is determined. If the voltage value measured by the detection and determination module is 1.5 V, then 1.5/12˜0.125 is calculated, rounding is performed, and the voltage value is determined zero. If the voltage value measured by the detection and determination module is −7.5 V, an absolute value is taken first, then 7.5/12˜0.625 is calculated, rounding is performed, and 1 times the battery pack voltage is determined. By analogy, the measured voltage value of the signal line can be determined more accurately.

For the battery system as described above, each battery pack of the plurality of battery packs connected with each other is in controllable connection with the signal line, the voltage value of the signal line is acquired, and the connection mode between the plurality of battery packs and/or the relative position between the plurality of battery packs are determined according to the voltage value. Through the above method, it is possible to automatically identify the connection state of each battery pack without any other operation after the user connects the battery pack arbitrarily, and then determine the connection mode and/or the relative position of each battery pack in the entire battery system, so that the battery system can be managed accurately.

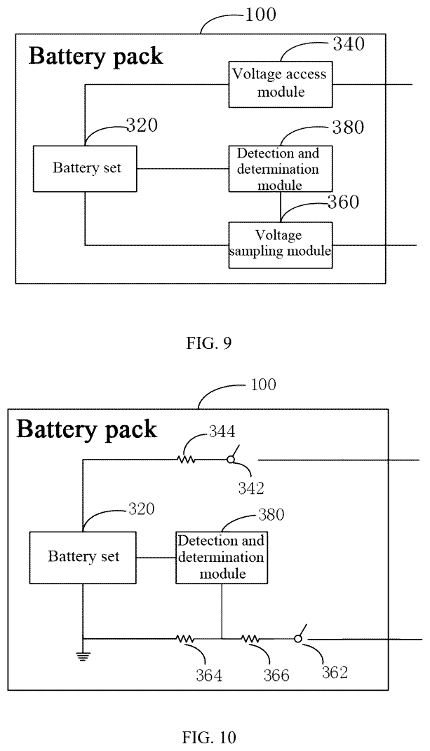

Optionally, in another embodiment proposed in the present disclosure, as shown in FIG. 9, in another case, the battery pack 100 in the battery system may include: a battery set 320, a voltage access module 340, a voltage sampling module 360, and a detection and determination module 380. A positive terminal of the battery set 320 is in controllable connection with a signal line through the voltage access module and a negative terminal of the battery set 320 is in controllable connection with the signal line through the voltage sampling module 360. It should be noted that the specific limitation for the controllable connection can refer to the aforementioned embodiment, which is not repeated here.

In some implementations, referring to FIG. 10, the voltage access module 340 may include at least one third switch 342 for controlling the voltage access module 340 to be in controllable connection with the signal line (not shown in the figure). The voltage sampling module 360 may include at least a voltage sampling circuit and a fourth switch 362, and the fourth switch 362 is configured to control the voltage sampling module 360 to be in controllable connection with the signal line (not shown in the figure). The voltage sampling circuit can be composed of a fourth resistor 364 and a fifth resistor 366 connected in series. The detection and determination module 380 is configured to detect a voltage between the fourth resistor 364 and the fifth resistor 366, and calculate a voltage value mapped onto the signal line according to a voltage dividing principle, which will be described in detail in the following embodiments. It should be noted that the detection and determination module 380 in this embodiment is disposed in at least one battery pack of the plurality of battery packs in the battery system, and can be implemented by the battery management system (BMS) of the battery pack. Optionally, the voltage sampling circuit in this embodiment may also be the voltage measuring circuit 184 mentioned in the above embodiment, and the voltage sampling circuit will not be repeatedly described here.

Optionally, the voltage access module 340 can directly be the third switch 342. Positive and negative terminals of the battery set 320 can be in controllable connection with the signal line through the third switch 342 and the voltage sampling module 360, respectively.

Optionally, the voltage access module 340 may include the third switch 342 and a third resistor 344. The battery set 320 is connected with the third resistor 344 and then connected with the third switch 342. The battery set may also be connected with the third switch 342 and then connected with the third resistor 344. The voltage sampling module 360 may include the fourth switch 362 and the voltage sampling circuit. The battery set 320 can be connected with the fourth switch 362 and the voltage sampling circuit sequentially, or can be connected with the voltage sampling circuit and the fourth switch 362 sequentially. An order of the sequential connection is not limited in this embodiment. In addition, the number of the third switch and the fourth switch is not limited in this embodiment, as long as both terminals of the battery set 320 can be in controllable connection with the signal line.

In some embodiments, as shown in FIG. 11, power interfaces (on a left side of a battery pack in FIG. 11) of a plurality of battery packs are connected with a power busbar to form a battery system. It should be noted that a specific connection mode between the plurality of battery packs shown in FIG. 11 does not constitute a specific limitation on this embodiment, but is only configured to illustrate that the plurality of battery packs may be connected in series, parallel, first connected in series to form a battery pack set and then connected in parallel, or first connected in parallel to form a battery pack set and then connected in series. In addition, both terminals of the battery set of the plurality of battery packs are in controllable connection with the signal line through the voltage access module 340 and the voltage sampling module 360 (on a right side of the battery pack in FIG. 11), respectively. It should be noted that in this embodiment, only one signal line is required, that is, the positive and negative terminals of the battery set in each battery pack are in controllable connection with the same signal line. When determining a connection mode and/or the relative position between the plurality of battery packs, the first battery pack in the battery system is served as a reference point, the detection and determination module (a BMS in the first battery pack) of the first battery pack is configured to control the voltage sampling module of the first battery pack to connect with the signal line. The detection and determination module is further configured to communicate with at least one second battery pack of the plurality of battery packs, so that the second battery pack controls the voltage access module of the second battery pack to connect with the signal line. The detection and determination module is further configured to acquire a voltage value of the signal line and determine, according to the voltage value, the connection mode and/or the relative position between the first battery pack and the second battery pack. A specific determination principle will be described in detail below. As another implementation mode, the detection and determination module (the BMS in the first battery pack) of the first battery pack is configured to control the voltage access module of the first battery pack to connect with the signal line. The detection and determination module is further configured to communicate with at least one second battery pack of the plurality of battery packs, so that the second battery pack controls the voltage sampling module of the second battery pack to connect with the signal line. The detection and determination module is further configured to communicate with the second battery pack, acquire a voltage value of the signal line detected by the detection and determination module of the second battery pack, and determine, according to the voltage value, the connection mode and/or the relative position between the first battery pack and the second battery pack.

The technical solution involved in this embodiment will be described in the following through specific implementations. This implementation is described by taking that the positive terminal of the battery set of each battery pack is connected with the voltage access module, and the negative terminal of the battery set is connected with the voltage sampling module as an example. However, it should be understood that this embodiment is not limited to this manner. Since both terminals of the battery set 320 of each battery pack are in controllable connection with the signal line, the BMS in the detection and determination module can control the fourth switch 362 in the voltage sampling module 360 of the first battery pack to be turned off (conducted), so that the negative terminal of the battery set 320 of the first battery pack is connected with the signal line through the voltage sampling module 360. The first battery pack can also communicate with the second battery pack, so that the third switch 342 of the voltage access module 340 of the second battery pack is turned off (conducted), and the positive terminal of the battery set of the second battery pack is connected with the signal line through the voltage access module. The first battery pack can communicate with the second battery pack in wired or wireless modes, and the wired communicating mode can be, for example, a connection through a CAN bus or a RS485 bus to perform communication.

The detection and determination module 380 is further configured to acquire a voltage value of the signal line measured by the voltage sampling module of the first battery pack and determine at least one selected from a group consisting of a connection mode and a relative position between the first battery pack and the second battery pack according to the voltage value.

Specifically, as described above, after the negative terminal of the battery set 320 of the first battery pack and the positive terminal of the battery set 320 of the second battery pack are connected with the signal line, the voltage sampling module 360 of the first battery pack can acquire the voltage value of the signal line and transmit the voltage value to the detection and determination module 380 through an Input/Output port of the detection and determination module 380. The detection and determination module 380 can execute a determination strategy according to the voltage value and determine the connection mode between the first battery pack and the second battery pack, and/or determine the relative position between the first battery pack and the second battery pack according to the determination strategy.

In an optional implementation, the detection and determination module is disposed in at least one first battery pack of the plurality of battery packs.

The detection and determination module is configured to control the voltage sampling module of the first battery pack to connect with the signal line.

The detection and determination module is configured to communicate with at least one second battery pack of the plurality of battery packs, so that the second battery pack controls the voltage access module of the second battery pack to connect with the signal line.

The detection and determination module is further configured to acquire a voltage value of the signal line measured by the voltage sampling module of the first battery pack and determine at least one selected from a group consisting of a connection mode and a relative position between the first battery pack and the second battery pack according to the voltage value.

Specifically, the detection and determination module 380 can be a BMS built in the first battery pack, which is configured to control the voltage sampling module 360 of the first battery pack, so that the negative terminal of the battery set of the first battery pack is connected with the signal line. Then the first battery pack can communicate with the plurality of second battery packs in sequence. The first battery pack makes the voltage access module 340 in one second battery pack close each time, so that the positive terminal of the second battery pack is connected with the signal line. At this time, the second battery pack can map a voltage thereof onto the signal line. The detection and determination module 380 in the first battery pack can sequentially acquire the voltage values of the signal line between the first battery pack and each second battery pack, which is collected by the first battery pack. This voltage value can characterize an actual voltage value between the negative terminal of the first battery pack and the positive terminal of the second battery pack after the first battery pack and the second battery pack are connected with each other, thus the connection mode and/or the relative position relationship between the first battery pack and each second battery pack can be determined according to the voltage value and the determination strategy.

For example, in a first case, assuming that the first battery pack and the second battery pack are connected in parallel, at this time, the voltage value measured by the detection and determination module in the first battery pack should be a positive value, and an absolute value of the voltage value is close to a voltage value of the first battery pack (or the second battery pack, since the voltage value of the first battery pack and the voltage value of the second battery pack are basically the same). Thus, if the acquired voltage value of the signal line is a positive value and is equal to or close to a voltage value of the battery pack, it can be determined that the first battery pack and the second battery pack are connected in parallel.

In a second case, assuming that the first battery pack and the second battery pack are connected in series. At this time, if the voltage value measured by the detection and determination module in the first battery pack is zero, it can be determined that the second battery pack is connected in series with the first battery pack, the positive terminal of the second battery pack is directly connected with the negative terminal of the first battery pack, and no other battery packs and/or battery pack sets are connected in series between the first battery pack and the second battery pack. If the voltage value measured by the detection and determination module in the first battery pack is a positive value and the voltage value is N times or close to N (N is a number greater than or equal to 2) times a voltage of a single battery pack, it can be determined that the second battery pack is connected in series with the first battery pack, and the negative terminal of the second battery pack is connected to the positive terminal side of the first battery pack in series, and a total of (N−2) battery packs and/or battery pack sets are connected in series between the negative terminal of the second battery pack and the positive terminal of the first battery pack. If the voltage value measured by the detection and determination module is a negative value, and an absolute value of the voltage value is M times or close to M (M is a number greater than or equal to 1) times the voltage of a single battery pack, it can be determined that the second battery pack is connected in series with the first battery pack, the positive terminal of the second battery pack is connected to the negative terminal side of the first battery pack in series, and a total of M battery packs and/or battery pack sets are connected in series between the positive terminal of the second battery pack and the negative terminal of the first battery pack.

In another optional implementation, the detection and determination module is disposed in at least one first battery pack of the plurality of battery packs.

The detection and determination module is configured to control the voltage access module of the first battery pack to connect with the signal line.

The detection and determination module is configured to communicate with at least one second battery pack of the plurality of battery packs, so that the second battery pack controls the voltage sampling module of the second battery pack to connect with the signal line.

The detection and determination module is further configured to acquire a voltage value of the signal line measured by the voltage sampling module of the second battery pack and determine at least one selected from a group consisting of a connection mode and a relative position between the first battery pack and the second battery pack according to the voltage value.

Specifically, the detection and determination module 380 can be a BMS built in the first battery pack, which is configured to control the third switch 342 in the voltage access module 340 of the first battery pack to be turned off (conducted), so that the positive terminal of the battery set of the first battery pack is connected with the signal line through the voltage access module 340. The first battery pack can also send a control instruction to the second battery pack through a communication connection (CAN or RS485) with the second battery pack, so that the second battery pack can control the fourth switch 362 in the voltage sampling module 360 of the second battery pack to be turned off (conducted) according to the control instruction, and cause the negative terminal of the battery set of the second battery pack to connect to the signal line through the voltage sampling module 360.

Specifically, as described above, after the positive terminal of the battery set of the first battery pack and the negative terminal of the battery set of the second battery pack are respectively connected with the signal line, the voltage sampling module 360 of the second battery pack can acquire the voltage value of the signal line. The first battery pack can communicate with the second battery pack so that the detection and determination module 380 of the first battery pack acquires the voltage value, and then determines the connection mode and/or the relative position relationship between the first battery pack and the second battery pack according to the voltage value and a corresponding determination strategy.

In some implementations, the detection and determination module 380 is disposed in the first battery pack (i.e., the first battery pack is served as a control host). The first battery pack can turn off the third switch 342 of the voltage access module 340 thereof, so that the positive terminal of the battery set of the first battery pack is connected with the signal line. Then the first battery pack can communicate with the second battery packs in sequence, so that the fourth switch 362 of the voltage sampling module 360 in the second battery pack is turned off, and the negative terminal of the battery set of the second battery pack is connected with the signal line. The detection and determination module in the first battery pack can sequentially acquire the voltage value between each second battery pack and the first battery pack collected by each second battery pack.

After the positive terminal of the battery set of the first battery pack and the negative terminal of the battery set of the second battery pack are connected with the signal line, the voltage sampling module 360 of the second battery pack is connected with the signal line. Therefore, the voltage sampling module in the second battery pack can acquire the voltage value of the signal line. The detection and determination module 380 of the first battery pack can sequentially acquire the voltage values of the signal line acquired by the voltage sampling module in each second battery pack through the communication connection with each second battery pack. The voltage value can characterize an actual voltage value between the positive terminal of the first battery pack and the negative terminal of the second battery pack after the first battery pack and the second battery pack are connected with each other, so that the connection mode and/or the relative position relationship between the first battery pack and each second battery pack can be determined according to the voltage value and the determination strategy.

For example, in a third case, assuming that the first battery pack and the second battery pack are connected in parallel, the voltage value acquired by the BMS in the detection and determination module of the first battery pack should be a positive value, and the voltage value is close to a voltage value of the second battery pack (or the first battery pack, since the first battery pack and the second battery pack are generally of the same type, and the voltage value of the first battery pack and the voltage value of the second battery pack are basically the same). If the acquired voltage value of the signal line is equal to or close to a negative voltage value of the battery pack, it can be determined that the first battery pack and the second battery pack are connected in parallel.

In a fourth case, assuming that the first battery pack and the second battery pack are connected in series. At this time, if the voltage value measured by the second battery pack and acquired by the detection and determination module is zero or close to zero, it can be determined that the second battery pack is connected in series with the first battery pack, and the negative terminal of the second battery pack is directly connected with the positive terminal of the first battery pack, and no other battery packs and/or battery pack sets are connected in series between the second battery pack and the first battery pack. If the voltage value acquired by the detection and determination module is a negative value, and an absolute value of the voltage value is M (M is a number greater than or equal to 1) times the voltage of the first battery pack, it can be determined that the second battery pack is connected in series with the first battery pack, the negative terminal of the second battery pack is connected to the positive terminal side of the first battery pack in series, and a total of M battery packs and/or battery pack sets are connected in series between the positive terminal of the first battery pack and the negative terminal of the second battery pack. If the voltage value acquired by the detection and determination module is a positive value, and the voltage value is N times or close to N (N is a number greater than or equal to 2) times a voltage of a single battery pack, it can be determined that the second battery pack is connected in series with the first battery pack, the positive terminal side of the second battery pack is connected with the negative terminal side of the first battery pack in series, and a total of (N−2) battery packs and/or battery pack sets are connected in series between the positive terminal of the second battery pack and the negative terminal of the first battery pack.

Based on the above determination strategy executed by the detection and determination module, it can be known that the detection and determination module is configured to control the voltage access module of the first battery pack to connect with the signal line. The detection and determination module is configured to communicate with at least one second battery pack of the plurality of battery packs, so that the second battery pack controls the voltage sampling module of the second battery pack to connect with the signal line. Connection modes of the first battery pack and the second battery pack are different, and voltage values of the signal line acquired by the detection and determination module are completely different. Therefore, a battery pack including the detection and determination module is served as the control host to measure the voltage value of the signal line, the connection modes of other battery packs and the battery pack and/or the relative position between other battery packs and the battery pack can be determined according to the voltage value.

It can be understood that the connection state and/or the relative position relationship of the first battery pack and the second battery pack can be determined by connecting an terminal (which can be a positive terminal or a negative terminal) of the battery set of the first battery pack and the other terminal (which can be a negative terminal or a positive terminal) of the battery set of the second battery pack to the signal line, and detecting the voltage value of the signal line. Repeating the above steps, a plurality of second battery packs are sequentially controlled to connect with the signal line, and a connection mode and/or a relative position relationship of each second battery pack and the first battery pack is determined. Thus, connection states of all battery packs in the entire battery system can be determined. It should be noted that only two specific implementations are illustrated above, but obviously this embodiment is not only limited to the two implementations. Those skilled in the art can understand that a voltage access module and a voltage sampling module connected with positive and negative terminals of each battery pack can be different, an terminal connected with the signal line can also be different each time, and battery packs that execute the determination strategy can also be different, which are based on the same principle and not repeated here. All of them should be included in the scope of this embodiment.

As a further possible implementation, after determining the connection mode between the first battery pack and the second battery pack and/or the relative position between the first battery pack and the second battery pack, the detection and determination module is configured to communicate with the at least one second battery pack, so that the second battery pack controls the voltage access module of the second battery pack to disconnect with the signal line. The detection and determination module is further configured to communicate with at least one third battery pack of the plurality of battery packs, so that the third battery pack controls a voltage access module of the third battery pack to connect with the signal line. The detection and determination module is further configured to acquire a voltage value of the signal line and determine a connection mode between the first battery pack and the third battery pack and/or a relative position between the first battery pack and the third battery pack according to the voltage value.

Or, the detection and determination module is configured to communicate with the at least one second battery pack, so that the second battery pack controls the voltage sampling module of the second battery pack to disconnect with the signal line. The detection and determination module is further configured to communicate with the at least one third battery pack of the plurality of battery packs, so that the third battery pack controls the voltage sampling module of the third battery pack to connect with the signal line. The detection and determination module is further configured to acquire a voltage value of the signal line. The detection and determination module is configured to determine the connection mode between the first battery pack and the third battery pack and/or the relative position between the first battery pack and the third battery pack according to the voltage value.

A specific connection mode and relative position determination strategy of the first battery pack and the third battery pack is completely the same as the determination strategy of the second battery pack described above, which is not repeated here.

In this way, repeating the above steps, voltage values of the signal line between the first battery packs and the second battery packs are acquired in sequence, and the connection mode and/or the relative position between each first battery pack and each second battery pack are determined. Thus the connection mode and/or the relative position of each battery pack in the entire battery system can be determined.

It should be further noted that although the voltage value of each battery pack in the battery system is basically the same or similar, a voltage difference also exists and cannot be ignored. Therefore, an absolute value of the voltage value measured by the detection and determination module may not be exactly equal to an integer multiple of a voltage of a single battery pack. To solve this problem, the voltage value measured by the detection and determination module can be divided by the voltage of a single battery pack and rounding is performed to obtain an integer so as to determine a specific multiple (i.e., N times, M times, or zero as mentioned above). For example, for a battery pack with a voltage of 12 V, if the voltage value measured by the detection and determination module is 32.5 V, then 32.5/12˜2.708 is calculated, rounding is performed and 3 times a battery pack voltage is determined. If the voltage value measured by the detection and determination module is 1.5 V, then 1.5/12˜0.125 is calculated, rounding is performed, and the voltage value is determined zero. If the voltage value measured by the detection and determination module is −7.5 V, an absolute value is taken first, then 7.5/12˜0.625 is calculated, rounding is performed, and 1 times the battery pack voltage is determined. By analogy, the measured voltage value of the signal line can be determined more accurately.

For the battery system as described above, each battery pack of the plurality of battery packs connected with each other is in controllable connection with the signal line, the voltage value of the signal line is acquired, and the connection mode between the plurality of battery packs and/or the relative position between the plurality of battery packs are determined according to the voltage value. Through the above method, it is possible to automatically identify the connection state of each battery pack without any other operation after the user connects the battery pack arbitrarily, and then determine the connection mode and/or the relative position of each battery pack in the entire battery system, so that the battery system can be managed accurately.

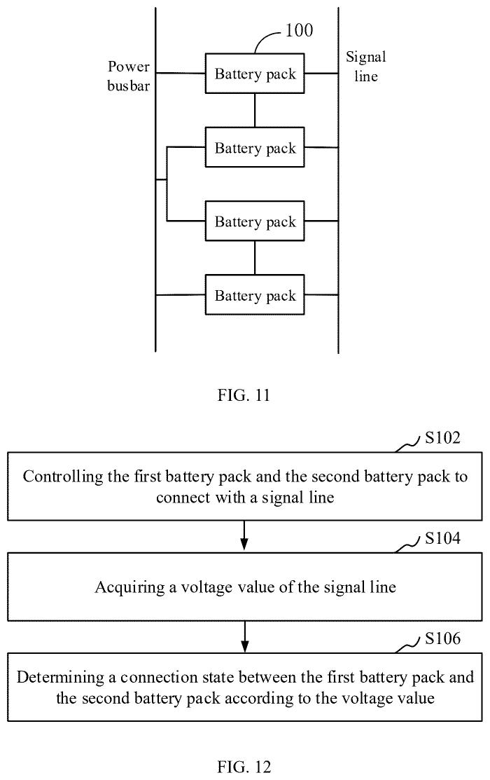

In an embodiment, as shown in FIG. 12, a battery pack connection state identification method is provided, and the identification method can be described using the battery system in FIG. 8 or FIG. 11 as an example, but is not limited to this and can also be applied to any aforementioned battery system. Specifically, the method can be applied to at least one first battery pack in a battery system composed of a plurality of battery packs, and the battery system further includes at least one second battery pack. The method includes the following steps:
S102: Controlling the first battery pack and the second battery pack to connect a signal line.

In this implementation, the first battery pack can communicate with the second battery pack. The battery pack is connected with the signal line according to a structure of the battery pack in different situations. Specifically, a first terminal of a battery set of the first battery pack and a second terminal of a battery set of the second battery pack are controlled to connect with the signal line, where the first terminal and the second terminal are two opposite and different terminal of the battery set, the first terminal is a positive terminal or a negative terminal, and the second polarity end is a negative terminal or a positive terminal. Thus, a voltage value between the first battery pack and the second battery pack can be mapped onto the signal line. In some implementations, for example, the battery pack is a battery pack shown in FIG. 1, a detection and determination module in the first battery pack can control a first voltage access module or a second voltage access module in the first battery pack to connect with the signal line. The detection and determination module in the first battery pack can control a first voltage access module or a second voltage access module in the second battery pack to connect with the signal line. In some other implementations, for example, the battery pack is a battery pack in FIG. 9, a detection and determination module in the first battery pack can control a voltage access module or a voltage sampling module in the first battery pack to connect with the signal line. Correspondingly, the detection and determination module in the first battery pack can control a voltage sampling module or a voltage access module in the second battery pack to connect with the signal line. Thus, different terminals of the first battery pack and the second battery pack are connected with the signal line.
S104: Acquiring a voltage value of the signal line.

In this implementation, the detection and determination module in the first battery pack acquires the voltage value of the signal line according to the different battery pack structures. In some implementations, a voltage measuring circuit 184 shown in FIG. 3 can be used to acquire the voltage value of the signal line. In some other optional implementations, a voltage measuring circuit shown in FIG. 6 can be used to acquire the voltage value of the signal line. In some other optional implementations, a voltage sampling module shown in FIG. 9 can be used to acquire the voltage value of the signal line. The voltage value can characterize an actual voltage value between the first terminal of the first battery pack and the second terminal of the second battery pack after the first battery pack and the second battery pack are connected with each other.
S106: Determining a connection relationship between the first battery pack and the second battery pack according to the voltage value.

In this implementation, the detection and determination module in the first battery pack can automatically identify a connection state between the first battery pack and the second battery pack according to a voltage rule and a voltage value of series or parallel connection. Optionally, the connection mode between the first battery pack and the second battery pack not only includes a connection state (such as series connection or parallel connection) of the first battery pack and the second battery pack, but also includes a relative position between the first battery pack and the second battery pack after being connected, the second battery pack connected to a positive terminal side or a negative terminal side of the first battery pack, and whether the other battery packs exist between the first battery pack and the second battery pack and the number of the other battery packs.

In the above battery pack connection state identification method, an actual voltage value between the first terminal of the first battery pack and the second terminal of the second battery pack is mapped onto the signal line by controlling the first battery pack and the second battery pack to connect with the signal line, and then the connection state between the first battery pack and the second battery pack can be determined according to the voltage value of the signal line. Therefore, after a user connects a plurality of battery packs to form a battery system, a connection state of the battery packs is automatically identified without additional operations, thereby a connection structure between battery systems formed by a plurality of battery packs, so that the battery pack and the battery system can be accurately managed.

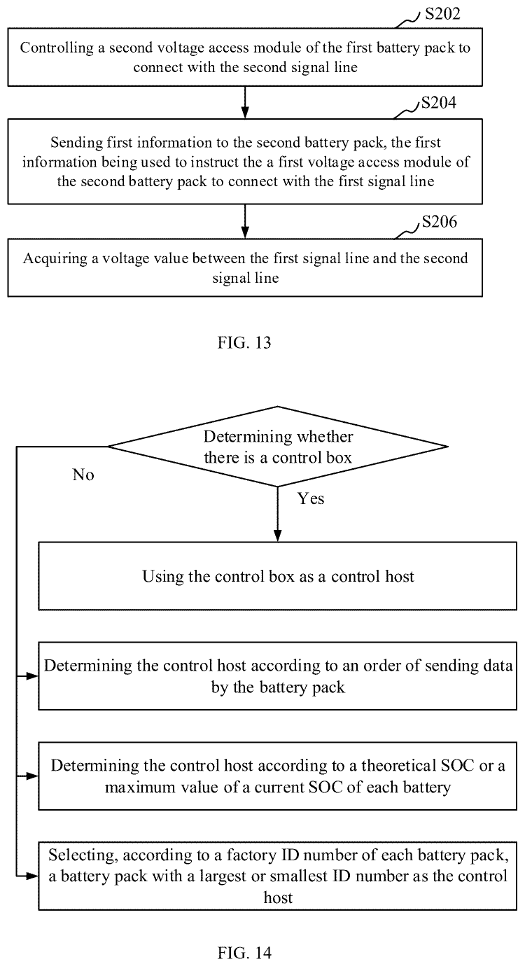

In an optional embodiment, as shown in FIG. 13, the first battery pack and the second battery pack are controllably connected with a first signal line through their own first voltage access modules, respectively, and controllably connected with a second signal line through their own second voltage access modules, respectively.

The controlling the first battery pack and the second battery pack to connect a signal line includes:
S202: Controlling the second voltage access module of the first battery pack to connect with the second signal line.

In this implementation, the first battery pack can be a control host in the battery system, and the first battery pack communicates with other slave battery packs to make the slave battery packs perform an action according to an instruction of the control host. When identifying the connection state of the battery pack, the first battery pack is served as a reference point to sequentially identify connection states of other slave battery packs relative to the first battery pack. Thus, a connection state of each battery pack in the entire battery system can be determined. As a possible implementation, the “controlling” may be that the control host controls the second voltage access module of the first battery pack to connect with the second signal line, and the control host can be the first battery pack or other battery packs or devices. The second battery pack can generally be a battery pack that needs to be determined a connection state thereof with the first battery pack. There may be one or a plurality of second battery packs. Generally, a connection state of one second battery pack and one first battery pack can be determined each time.

In this implementation, before executing step S122, a charging and discharging circuit of each battery pack needs to be opened to achieve interconnection between all the battery packs. The step can be executed during a power-on and self-test phase of the battery system. Subsequently, the second voltage access module of the first battery pack is in controllable connection with the second signal line. As the battery system described above, two terminals of a battery cell unit of the first battery pack are in controllable connection with the first signal line and the second signal line via the first voltage access module and the second voltage access module, respectively. Optionally, a positive terminal of the battery cell unit of the first battery pack is in controllable connection with the first signal line via the first voltage access module, and a negative terminal of the battery cell unit of the first battery pack is in controllable connection with the second signal line via the second voltage access module, which is not limited to this. The negative terminal of the battery cell unit of the first battery pack is in controllable connection with the first signal line via the first voltage access module, and the positive terminal of the battery cell unit of the first battery pack is in controllable connection with the second signal line via the second voltage access module, which is not limited here. When the second voltage access module of the first battery pack is controlled to connect with the second signal line, the first voltage access module of the first battery pack is kept disconnected with the first signal line.
S204: Sending first information to the second battery pack. The first information is used to instruct the first voltage access module of the second battery pack to connect with the first signal line.

In this implementation, the first battery pack is served as the control host and can send the first information to the second battery pack through a communication connection established with the second battery pack. After the second battery pack receives the first information, the first voltage access module of the second battery pack can be controlled to connect with the first signal line according to the instruction of the first information, and the second voltage access module of the second battery pack is kept disconnected with the second signal line.

The acquiring a voltage value of the signal line includes:
S206: Acquiring a voltage value between the first signal line and the second signal line.

In this implementation, when one end of the first battery pack and one end of the second battery pack are connected with the first signal line and the second signal line, respectively, the connection state between the first battery pack and the second battery pack can be reflected by the voltage value between the first signal line and the second signal line. Therefore, the voltage value between the first signal line and the second signal line can be acquired by the detection and determination module in the battery pack.

In this embodiment, by controlling different voltage access modules of the first battery pack and the second battery pack to connect different signal lines, that is, controlling one voltage access module of the first battery pack to connect with the first signal line and controlling the other voltage access module of the second battery pack to connect with the second signal line, then the voltage value between the first signal line and the second signal line is measured, and a voltage difference value between the first signal line and the second signal line can be determined. Therefore, after a user connects a plurality of battery packs without additional operations, the voltage value between the first signal line and the second signal line is automatically acquired through this solution, thereby a connection structure between battery systems formed by a plurality of battery packs, so that the battery pack and the battery system can be accurately managed.

In a possible implementation, before controlling the second voltage access module of the first battery pack to connect with the second signal line, the method further includes:

Determining a control host according to a preset rule and allocating a slave address of each battery pack.

In this implementation, after the battery system is connected and communication connection is established, each battery pack is turned on. Each battery pack can check whether a its own voltage and a voltage across both ends are consistent through its voltage measuring circuit, and if the voltages are consistent or not significantly different, for example, when a difference value is less than a preset range threshold, it can be determined that the connection is normal. Otherwise, it indicates that the connection of the battery pack exist error, and the battery pack can give an alarming prompt. After the battery pack completes a power-on self test, the plurality of battery packs need to compete for a host and slaves and the addresses are allocated. A specific method for competing for the host and the slaves is as shown in FIG. 14, whether there is a control box is determined, and the control box can be a control box with a display screen or a control box without a display screen. In this implementation, the control box is disposed as an independent module in the battery system, which is completely the same as the detection and determination module disposed as an independent module in the battery system described previously, which is not repeated here. If there is a control box, the control box is served as the control host. Optionally, in this implementation, the step of determining whether there is a control box can be omitted. When there is a control box in the battery system, the control box can directly perform communication through communication connection with each battery pack and notify each battery pack that the control box is served as the control host. Further, if there is no control box, the control host can be determined according to the preset rule. A specific preset rule includes any one of the following manners: determining the control host according to an order of sending data by the battery pack, or determining the control host according to a theoretical SOC or a maximum value of a current SOC of each battery, or selecting, according to a factory ID number of each battery pack, a battery pack with a largest or smallest ID number as the control host. The factory ID number of each battery pack is unique and increases sequentially according to the date of manufacture. As a preferred implementation, a battery pack with the largest theoretical SOC or a battery pack with the largest factory ID number is selected as the control host, that is, the latest battery pack is selected as the control host, thereby ensuring the operation stability and sustainability of the entire battery system.

When the plurality of battery packs are connected with each other, in order to achieve RS485 or CAN bus communication of the plurality of battery packs, each battery pack needs an address. Therefore, after determining the control host, slave addresses can be allocated to other battery packs in sequence according to the factory ID number of each battery pack.

In addition, when the plurality of battery packs are connected with each other, the plurality of battery packs can be connected when the SOC and/or a voltage of each battery pack is basically the same, thereby avoiding a large circulating current generated due to a overlarge voltage difference between the battery packs and leading to unexpected danger, and can also achieve the best performance of the connected battery system.

In addition, when the plurality of battery packs are connected in series and/or parallel, they must be operated under any of the following conditions:
(1) All the battery packs enter a shutdown (or sleep) state.
(2) In a normal startup and working state, a communication line is first conducted and communication is established between battery packs, and then a series-parallel connection operation can be performed.

If any of the above conditions is not met, that is, if the communication line is not connected first (on the basis of establishing the communication) and a connection error occurs in a startup state, the battery pack will perform overcurrent or short-circuit protection on its own. Therefore, through the above manner, the safety hazard is eliminated and the losses is reduced as possible when an incorrect operation occurs.

After determining the control host, the connection state between the first battery pack and the second battery pack is determined by subsequently controlling the first battery pack and the second battery pack through the control host. An embodiment shown in FIG. 13 is a battery pack connection state identification method executed by the first battery pack as the control host. As an optional implementation, the battery pack connection state identification method can also be executed according to the following steps, the steps are executed by the control box in the battery system, and the method includes:

Sending first information to the first battery pack. The first information is used to instruct the second voltage access module of the first battery pack to connect with the second signal line.

Sending control information of the first information to the second battery pack. The control information is used to instruct the first voltage access module of the second battery pack to connect with the first signal line.

Acquiring a voltage value between the first signal line and the second signal line and determining a connection state between the first battery pack and the second battery pack according to the voltage value.

In this implementation, the control box is served as the control host and sequentially communicates with the first battery pack and the second battery pack, thereby connecting different voltage access modules of the first battery pack and the second battery pack to the first signal line and the second signal line. The connection state between the first battery pack and the second battery pack is then identified according to the measured voltage value. It can be understood that difference between this implementation and the previously described implementation is only the executing subject, and the basic principle is the same, which is not repeated here.

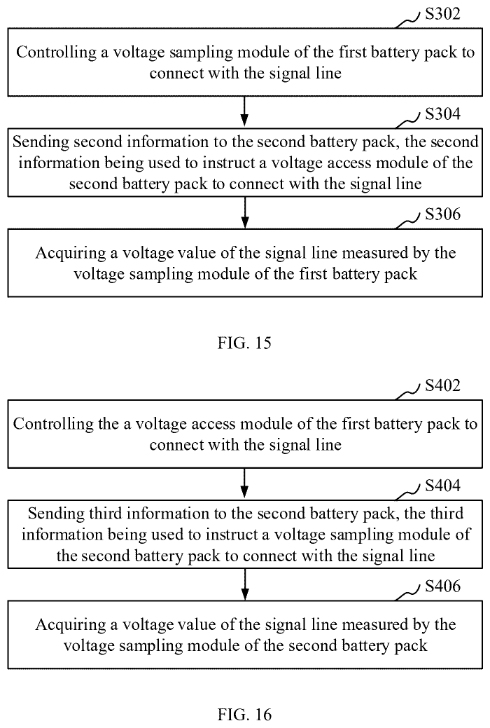

In another optional embodiment, as shown in FIG. 15, the first battery pack and the second battery pack are controllably connected with the signal line through their own voltage access modules and voltage sampling modules, respectively. The controlling the battery pack to connect with the signal line includes:
S302: Controlling the voltage sampling module of the first battery pack to connect with the signal line.

In this implementation, the first battery pack may be a control host in the battery system, and the second battery pack may be a slave in the battery system. The first battery pack communicates with other slave battery packs to cause the slave battery packs to perform an action according to an instruction of the control host. When identifying the connection state of the battery pack, the first battery pack is used as a reference point to sequentially identify a connection state of other slave battery packs relative to the first battery pack. The first battery pack can turn off a switch in the voltage sampling module of the first battery pack to cause the first battery pack to connect with the signal line through the voltage sampling module.
S304: Sending second information to the second battery pack. The second information is used to instruct the voltage access module of the second battery pack to connect with the signal line.

In this implementation, the first battery pack is served as a control host and sends the second information to the second battery pack through communication connection established with the second battery pack. After the second battery pack receives the second information, the voltage access module of the second battery pack can be controlled to connect with the signal line according to the instruction of the second information, and the voltage sampling module of the second battery pack is kept disconnected with the signal line.

The acquiring a voltage value of the signal line includes:
S306: Acquiring a voltage value of the signal line measured by the voltage sampling module of the first battery pack.

In this implementation, because the voltage sampling module of the first battery pack is connected with the signal line, the voltage value of the signal line can be measured through the voltage sampling module of the first battery pack. Then, a BMS in the detection and determination module of the first battery pack can acquire the voltage value of the signal line measured by the voltage sampling module of the first battery pack.

In still another optional embodiment, as shown in FIG. 16, the first battery pack and the second battery pack are controllably connected with the signal line through their own voltage access module and voltage sampling module respectively, and the controlling the battery pack to connect with the signal line includes:
S402: Controlling the voltage access module of the first battery pack to connect with the signal line.

In this implementation, the first battery pack can also turn off a switch in the voltage access module of the first battery pack, so that the first battery pack is connected with the signal line through the voltage access module.
S404: Sending third information to the second battery pack. The third information is used to instruct the voltage sampling module of the second battery pack to connect with the signal line.

In this implementation, the first battery pack is served as a control host and can send the third information to the second battery pack through communication connection established with the second battery pack. After the second battery pack receives the third information, the voltage sampling module of the second battery pack can be controlled to connect with the signal line according to the instruction of the third information. The voltage access module of the second battery pack is kept disconnected with the signal line. The acquiring a voltage value of the signal line includes:
S406: Acquiring a voltage value of the signal line measured by the voltage sampling module of the second battery pack.

In this implementation, since the voltage sampling module of the second battery pack is connected with the signal line, the voltage sampling module of the second battery pack can measure the voltage value of the signal line. Then, the BMS in the detection and determination module in the first battery pack can communicate with the voltage sampling module of the second battery pack through the signal line to acquire the voltage value of the signal line measured by the voltage sampling module of the second battery pack.

In this embodiment, by using different modules in the first battery pack and the second battery pack to connect with the signal line, the voltage sampling module in the first battery pack or the second battery pack can acquire the voltage value of the signal line, various different connection scenarios can be adapted and the connection state of the battery pack can be better determined.

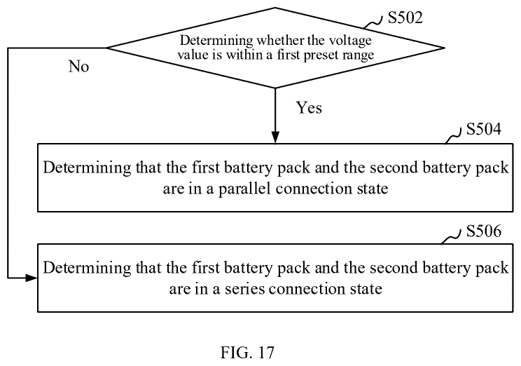

In an embodiment, as shown in FIG. 17, acquiring a voltage value between the first signal line and the second signal line and determining a connection state between the first battery pack and the second battery pack according to the voltage value include at least one of the following:
S502: Determining whether the voltage value is within a first preset range.
S504: In response to that the voltage value is within the first preset range, determining that the first battery pack and the second battery pack are in a parallel connection state.
S506: In response to that the voltage value is not within the first preset range, determining that the first battery pack and the second battery pack are in a series connection state.

In this implementation, on the basis of the embodiment shown in FIG. 12, those skilled in the art know that if two battery packs are in the parallel connection state, the voltage value measured between the first signal line and the second signal line should be equal to or close to a voltage of the battery pack or a negative voltage of the battery pack. For example, assuming that the first battery pack and the second battery pack are connected in parallel, when a negative terminal of the first battery pack is connected with the second signal line via the second voltage access module, and a positive terminal of the second battery pack is connected with the first signal line via the first voltage access module, the voltage value measured between the signal lines should be equal to or close to a voltage of the battery pack. On the contrary, when a positive terminal of the first battery pack is connected with the second signal line via the second voltage access module, and a negative terminal of the second battery pack is connected with the first signal line via the first voltage access module, the measured voltage value between the signal lines should be equal to or close to a negative voltage of the battery pack. In addition, considering a possible slight voltage difference between the first battery pack and the second battery pack, the first preset range is set to ensure the accuracy of an identification process.

Exemplarily, in a practical situation, the first preset range can be set according to a rated voltage value of the battery pack. For example, when a rated voltage of a single battery pack is 12 V, the first preset range can be set to 10.5 V to 13.8 V or −13.8 V to −10.5 V. The preset range is only an example and can be specifically set by referring to a design document of the battery pack.

Specifically, in an implementation, if the positive terminals of the first battery pack and the second battery pack are controllably connected with the first signal line through their own first voltage access modules, respectively, and negative terminals of the first battery pack and the second battery pack are controllably connected with the second signal line through their own second voltage access modules, respectively, the first preset range can be equal to or close to a voltage range of the battery pack. For example, if the rated voltage of the first battery pack or the second battery pack is 12 V, the first preset range can be between 10.5 V and 13.8 V.

In another implementation, if the negative terminals of the first battery pack and the second battery pack are controllably connected with the first signal line through their first voltage access modules, respectively, and the positive terminals of the first battery pack and the second battery pack are controllably connected with the second signal line through their own second voltage access modules, respectively, the first preset range can be close to a negative voltage value of the first battery pack or the second battery pack. For example, if the rated voltage of the first battery pack or the second battery pack is 12 V, the first preset range can be between −13.8 V and −10.5 V.

Optionally, on the basis of the embodiment shown in FIG. 15 or FIG. 16, if the first battery pack and the second battery pack are connected in parallel, the voltage value of the signal line measured by the voltage sampling module of the first battery pack should be equal to or close to a voltage of the battery pack or a negative voltage of the battery pack. For example, assuming that the first battery pack and the second battery pack are connected in parallel, when a negative terminal of a battery set of the first battery pack is connected with the signal line through the voltage sampling module, and a positive terminal of the battery set of the second battery pack is connected with the signal line through the voltage access module, the voltage value of the signal line measured by the voltage sampling module should be equal to or close to a voltage of the battery pack. When the positive terminal of the first battery pack is connected with the signal line through the voltage access module, and the negative terminal of the second battery pack is connected with the signal line through the voltage sampling module, the voltage of the signal line measured by the voltage sampling module of the second battery pack should be equal to or close to a negative voltage of the battery pack.

In addition, considering a possible slight voltage difference between the first battery pack and the second battery pack, the first preset range can be set to ensure the accuracy of the identification process. Specifically, a range of the first preset range can be determined according to an access condition of the positive terminal or negative terminal of the battery pack to the signal line, thereby determining whether the acquired voltage value is within the first preset range. If the voltage value is within the first preset range, then according to a parallel connection relationship, it can be determined that the first battery pack and the second battery pack are in a parallel connection state. If the voltage value is not within the first preset range, it can be determined that the first battery pack and the second battery pack are in a series connection state.

Exemplarily, in a practical situation, the first preset range can be set according to the rated voltage value of the battery pack. For example, when a rated voltage of a single battery pack is 12 V, the first preset range can be set to 10.5 V to 13.8 V or −13.8 V to −10.5 V. The preset range is only an example and can be specifically set by referring to the design document of the battery pack.

In some exemplary embodiments, if there are a plurality of second battery packs, a voltage value of the signal line between each second battery pack and the first battery pack can be sequentially determined, thereby determining the series or parallel connection state between each second battery pack and the first battery pack, and ultimately determining the connection state of all second battery packs relative to the first battery pack. Then, according to the connection state, a total voltage and a total capacity of batteries containing all the battery packs can be calculated. Therefore, further, on the basis of the embodiment shown in FIG. 12, after the steps of acquiring the voltage value of the signal line and determining the connection state between the first battery pack and the second battery pack according to the voltage value, the identification method further includes:

Sending first control information to the second battery pack, the first control information used to instruct the first voltage access module of the second battery pack to disconnect with the first signal line; sending second control information to a third battery pack, the second control information used to instruct the first voltage access module of the third battery pack to connect with the first signal line; and acquiring the voltage value between the first signal line and the second signal line and determining the connection state between the first battery pack and the third battery pack according to the voltage value.

Optionally, on the basis of the embodiment implemented in FIG. 15 or FIG. 16, the identification method may further include:

Sending third control information to the second battery pack, the third control information used to instruct the voltage access module of the second battery pack to disconnect with the signal line.

Sending fourth control information to the third battery pack, the fourth control information used to instruct the voltage access module of the third battery pack to connect with the signal line; or, sending fifth control information to the second battery pack, the fifth control information used to instruct the voltage sampling module of the second battery pack to disconnect with the signal line.

Sending sixth control information to the third battery pack, the sixth control information used to instruct the voltage sampling module of the third battery pack to connect with the signal line.

In this implementation, after identifying the connection state between the first battery pack and the second battery pack, the first battery pack is kept connected with the signal line, the second battery pack is controlled to disconnect with the signal line, and the third battery pack is controlled to connect with the signal line, thereby identifying the connection state between the first battery pack and the third battery pack. Repeating the above steps, the connection state between the battery pack and the first battery pack is identified after sequentially connecting different battery packs to the signal line until all battery packs are identified. Thus, the connection state of each battery pack in the entire battery system can be identified.

In a possible implementation, after identifying that the battery packs are only connected in parallel, whether theoretical SOCs of all batteries connected in parallel are consistent is calculated. If a difference is too large, it indicates that the parallel connection is unreasonable. An actual capacity of the battery packs connected in parallel is a value obtained after the rated capacity of each battery pack multiplied by SOH is summed. When identifying that there are battery packs connected in series and parallel at the same time, the final SOC is determined by a minimum SOC value of all battery packs or battery pack sets connected in series (the plurality of battery packs are connected in parallel and as a whole, and the SOC acquired after the parallel connection is a sum of the SOCs of the plurality of battery packs).

In this embodiment, by acquiring the voltage value of the signal line and comparing the voltage value with a preset range, even in the presence of a voltage difference between the battery packs, the method can be still adapted to conditions of different battery systems, and the connection state between the first battery pack and the second battery pack can be accurately determined.

In an embodiment, in response to that the voltage value is not within the first preset range, determining that the first battery pack and the second battery pack are in a series connection state, further includes:

Determining at least one selected from a group consisting of a relative position between the first battery pack and the second battery pack, and the number of battery packs connected in series according to the voltage value.

In this implementation, the relative position can be understood as a position where the second battery pack is connected with the first voltage access module or the second voltage access module in the first battery pack, or a position where the second battery pack is connected with a positive terminal side or a negative terminal side of the first battery pack. When the second battery pack is connected with the positive terminal side of the first battery pack, the negative terminal of the second battery pack is connected with the positive terminal of the first battery pack. When the second battery pack is connected with the negative terminal side of the first battery pack, the positive terminal of the second battery pack is connected with the negative terminal of the first battery pack.

In this implementation, when it is determined that the first battery pack and the second battery pack are in a series connection state, generally, it may include that the first battery pack and the second battery pack are directly connected in series, that is, there are no other battery packs therebetween. It can also be that the first battery pack and the second battery pack are indirectly connected in series, that is, there is at least one battery pack between the first battery pack and the second battery pack, or there is at least one battery pack set between the first battery pack and the second battery pack, or there is a battery pack and a battery pack set between the first battery pack and the second battery pack. The battery pack set includes a plurality of battery packs connected in parallel. Therefore, when the first battery pack and the second battery pack are in the series connection state, a relative position relationship of the first battery pack and the second battery pack can be determined according to a voltage value between the battery packs in the series connection state, that is, the second battery pack is connected with a first voltage access module or a second voltage access module of the first battery pack.

In this implementation, when the first battery pack and the second battery pack are in the series connection state, the relative position relationship of the first battery pack and the second battery pack and the number of the battery packs connected in series can be determined according to the voltage value, so that a connection structure in the first battery pack and the second battery pack can be better determined.

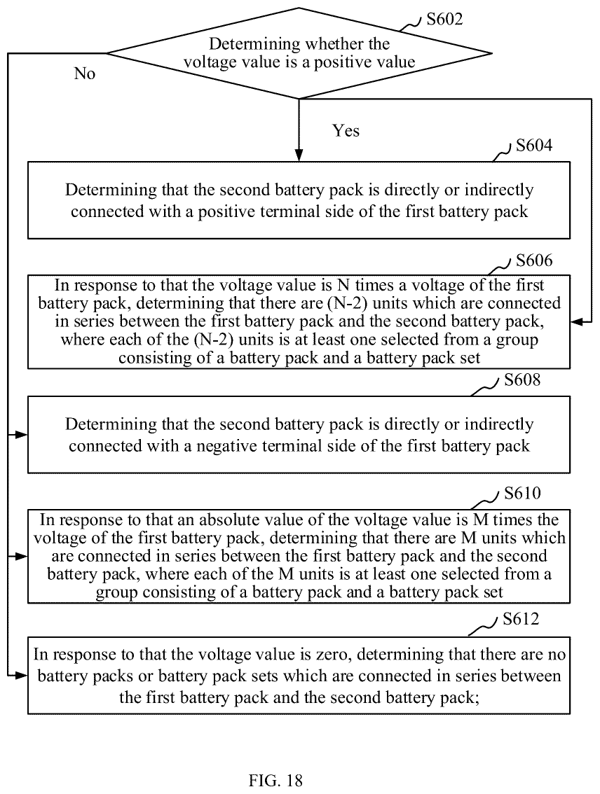

In an embodiment, as shown in FIG. 18, if positive terminals of the first battery pack and the second battery pack are controllably connected with the first signal line through their own first voltage access modules respectively, and negative terminals of the first battery pack and the second battery pack are controllably connected with the second signal line through their own second voltage access modules, respectively, or if the positive terminals of the first battery pack and the second battery pack are controllably connected with the signal line through their own voltage access modules, respectively, and the negative terminals of the first battery pack and the second battery pack are controllably connected with the signal line through their own voltage sampling modules, respectively, the determining a connection state between the first battery pack and the second battery pack according to the voltage value, or the determining at least one selected from a group consisting of a of relative position between the first battery pack and the second battery pack, and the number of battery packs connected in series includes at least one of the following:
S602: Determining whether the voltage value is a positive value.
S604: In response to that the voltage value is a positive value, determining that the second battery pack is directly or indirectly connected with the positive terminal side of the first battery pack.
S606: In response to that the voltage value is a positive value and the voltage value is N times a voltage of the first battery pack, determining that there are (N−2) units which are connected in series between the first battery pack and the second battery pack, where each of the (N−2) units is at least one selected from a group consisting of a battery pack and a battery pack set.
S608: In response to that the voltage value is a negative value or zero, determining that the second battery pack is directly or indirectly connected with a negative terminal side of the first battery pack.
S610: In response to that the voltage value is a negative value and an absolute value of the voltage value is M times the voltage of the first battery pack, determining that there are M units which are connected in series between the first battery pack and the second battery pack, where each of the M units is at least one selected from a group consisting of a battery pack and a battery pack set.
S612: In response to that the voltage value is zero, determining that there are no battery packs or battery pack sets which are connected in series between the first battery pack and the second battery pack.

N is a number greater than or equal to 2, M is a number greater than 1, and the battery pack set includes the plurality of battery packs connected in parallel.

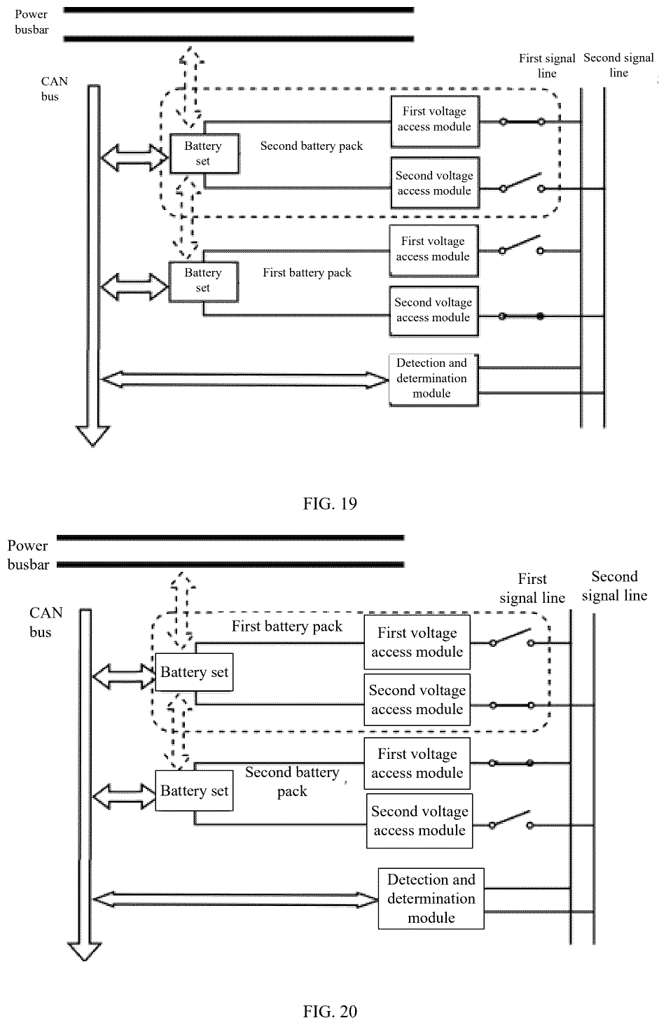

In some embodiments of the present disclosure, the positions of the first voltage access module and the second voltage access module in the first battery pack and the second battery pack are usually the same, that is, the first battery pack and the second battery pack are battery packs with the same structure. Specifically, after determining the voltage value between the first battery pack and the second battery pack, since the structure and connection mode between the battery packs have already been determined, the relative position between the first battery pack and the second battery pack and/or the number of battery packs connected in series between the first battery pack and the second battery pack can be determined according to the voltage value. As shown in FIG. 19 and FIG. 20, the first battery pack and the second battery pack marked in FIG. 19 and FIG. 20 are described as examples.

As shown in FIG. 19, when the negative terminal of the first battery pack is connected with the second signal line and the positive terminal of the second battery pack is connected with the first signal line, if the measured voltage value is a positive value, the negative terminal of the second battery pack is connected with the positive terminal of the first battery pack, that is, the second battery pack is connected with the positive terminal side (the first input module) of the first battery pack. If the voltage value is N times or close to N (N is a number greater than or equal to 2) times the voltage of a single battery pack, it can be determined that the second battery pack is connected in series with the first battery pack, and the negative terminal of the second battery pack is connected with the positive terminal of the first battery pack, and a total number of battery packs and/or battery pack sets connected in series between the negative terminal of the second battery pack and the positive terminal of the first battery pack are (N−2).

As shown in FIG. 20, when the negative terminal of the first battery pack is connected with the second signal line and the positive terminal of the second battery pack is connected with the first signal line, if the measured voltage value is zero or close to zero, it can be determined that the positive terminal of the second battery pack is directly connected with the negative terminal of the first battery pack, that is, the second battery pack directly is connected with the negative terminal side (the second input module) of the first battery pack, and no other battery packs or battery pack sets are connected in series between the second battery pack and the first battery pack. If the measured voltage value is a negative value, it can be determined that the second battery pack is connected in series with the first battery pack, and the positive terminal of the second battery pack is connected with the negative terminal of the first battery pack, that is, the second battery pack is connected with the negative terminal side (the second input module) of the first battery pack. If the measured voltage value is a negative value, and an absolute value of the voltage value is M times or close to M (M is a number greater than or equal to 1) times the voltage of a single battery pack, it can be determined that the second battery pack is connected in series with the first battery pack, the positive terminal of the second battery pack is connected with the negative terminal of the first battery pack, that is, the second battery pack is connected with the negative terminal side (the second input module) of the first battery pack, and a total number of battery packs and/or battery pack sets connected in series between the negative terminal of the second battery pack and the positive terminal of the first battery pack are M.

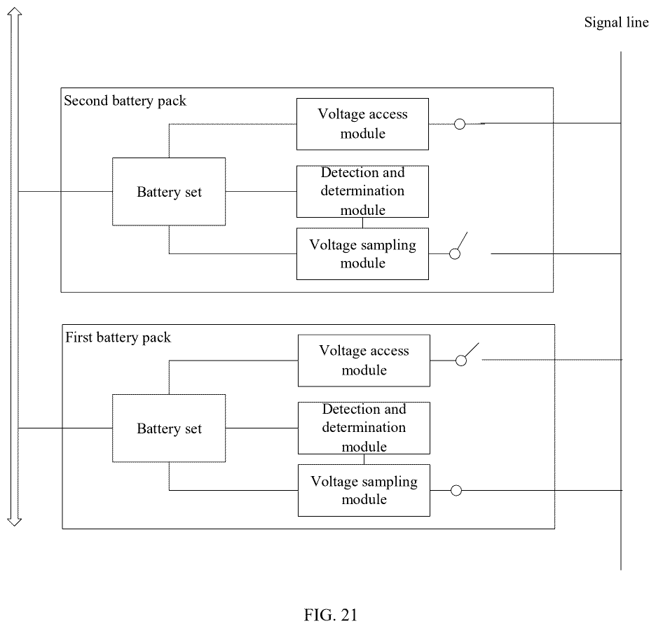

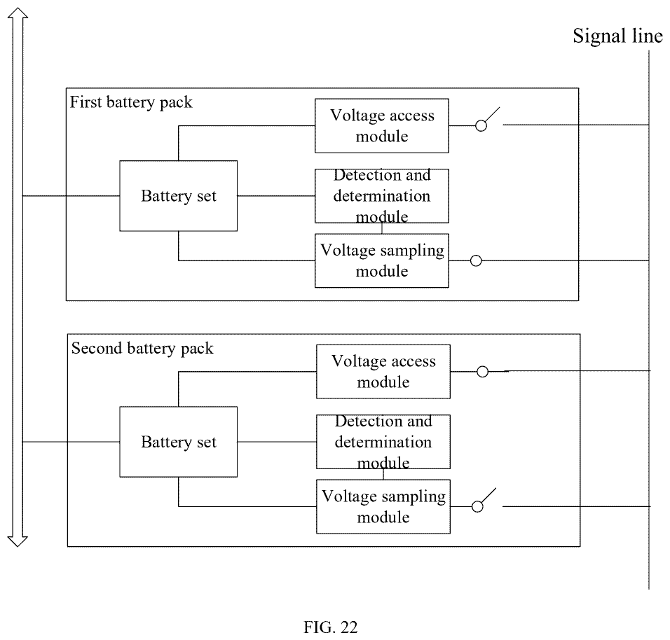

In some other embodiments of the present disclosure, positions of the voltage access module and the voltage sampling module in the first battery pack and the second battery pack are also constantly the same, that is, the first battery pack and the second battery pack are battery packs with the same structure. Since the connection state between the first battery pack and the second battery pack are determined, the relative position between the first battery pack and the second battery pack and/or the number of battery packs connected in series between the first battery pack and the second battery pack can be determined according to the voltage value of the signal line, and as shown in FIG. 21 and FIG. 22, the first battery pack and the second battery pack marked in FIG. 21 and FIG. 22 are described as examples.

As shown in FIG. 21, when the negative terminal of the battery set of the first battery pack is connected with the signal line through the voltage sampling module, and the positive terminal of the battery set of the second battery pack is connected with the signal line through the voltage access module, if the voltage value measured by the first battery pack is a positive value, it can be determined that the negative terminal of the second battery pack is connected with the positive terminal side (the voltage access module) of the first battery pack. If the measured voltage value of the first battery pack is N times or close to N (N is a number greater than or equal to 2) times the voltage of a single battery pack, it can be determined that the first battery pack is connected in series with the second battery pack, and the negative terminal of the second battery pack is connected with the positive terminal of the first battery pack, and a total number of battery packs and/or battery pack sets connected in series between the negative terminal of the second battery pack and the positive terminal of the first battery pack are (N−2).

As shown in FIG. 22, when the negative terminal of the battery set of the first battery pack is connected with the signal line through the voltage sampling module, and the positive terminal of the battery set of the second battery pack is connected with the signal line through the voltage access module. If the measured voltage value of the first battery pack is zero or close to zero, it can be determined that the positive terminal of the second battery pack is directly connected with the negative terminal of the first battery pack, that is, the second battery pack directly is connected with the negative terminal side (the voltage sampling module) of the first battery pack, and no other battery packs or battery pack sets are connected in series between the second battery pack and the first battery pack. If the measured voltage value of the first battery pack is a negative value, it can be determined that the second battery pack is connected in series with the first battery pack, and the positive terminal of the battery set of the second battery pack is connected with the negative terminal side (the voltage sampling module) of the battery set of the first battery pack in series. If the measured voltage value of the first battery pack is a negative value, and an absolute value of the voltage value is M times or close to M (M is a number greater than or equal to 1) times the voltage of a single battery pack, it can be determined that the second battery pack is connected in series with the first battery pack, the positive terminal of the battery set of the second battery pack is connected with the negative terminal side (the voltage sampling module) of the first battery pack in series, and a total number of battery packs and/or battery pack sets connected in series between the negative terminal of the second battery pack and the positive terminal of the first battery pack are M. In this implementation, it should be noted that the above-mentioned measured voltage value of the first battery pack can generally be the voltage value measured by the voltage sampling module in the first battery pack.

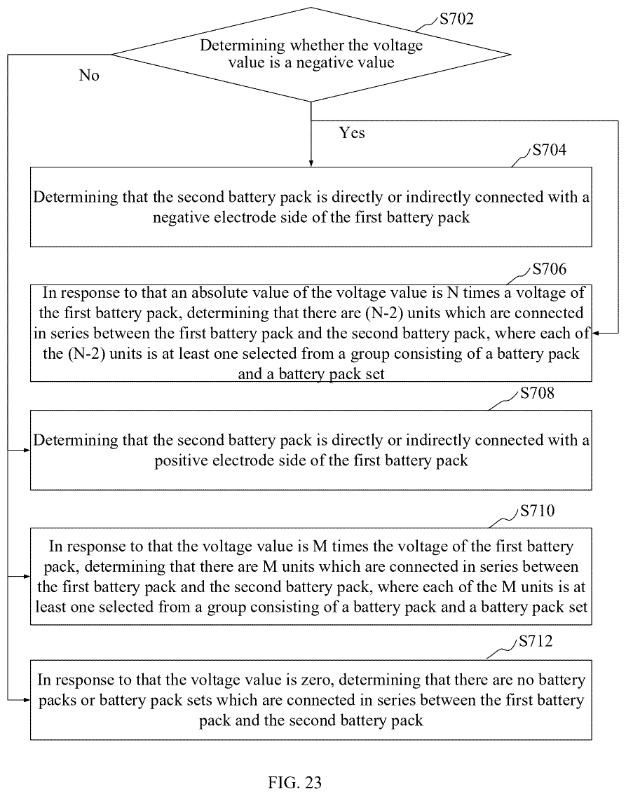

In another implementation, as shown in FIG. 23, if negative terminals of the first battery pack and the second battery pack are controllably connected with the first signal line through their own first voltage access modules, respectively, and positive terminals of the first battery pack and the second battery pack are controllably connected with the second signal line through their own second voltage access modules, respectively, or, if negative terminals of the first battery pack and the second battery pack are controllably connected with the signal line through their own voltage access modules, respectively, and positive terminals of the first battery pack and the second battery pack are controllably connected with the signal line through their own voltage sampling modules, respectively, then the determining a connection state between the first battery pack and the second battery pack, or the determining at least one selected from a group consisting of a of relative position between the first battery pack and the second battery pack, and the number of battery packs connected in series includes at least one of the following:
S702: Determining whether the voltage value is a negative value;
S704: In response to that the voltage value is a negative value, determining that the second battery pack is directly or indirectly connected with a negative terminal side of the first battery pack.
S706: In response to that the voltage value is a negative value and an absolute value of the voltage value is N times a voltage of the first battery pack, determining that there are (N−2) units which are connected in series between the first battery pack and the second battery pack, where each of the (N−2) units is at least one selected from a group consisting of a battery pack and a battery pack set.
S708: In response to that the voltage value is a positive value or zero, determining that the second battery pack is directly or indirectly connected with a positive terminal side of the first battery pack.
S710: In response to that the voltage value is a positive value and the voltage value is M times the voltage of the first battery pack, determining that there are M units which are connected in series between the first battery pack and the second battery pack, where each of the M units is at least one selected from a group consisting of a battery pack and a battery pack set.
S712: In response to that the voltage value is zero, determining that there are no battery packs or battery pack sets which are connected in series between the first battery pack and the second battery pack.

N is a number greater than or equal to 2, M is a number greater than or equal to 1, and the battery pack set includes a plurality of battery packs connected in parallel.

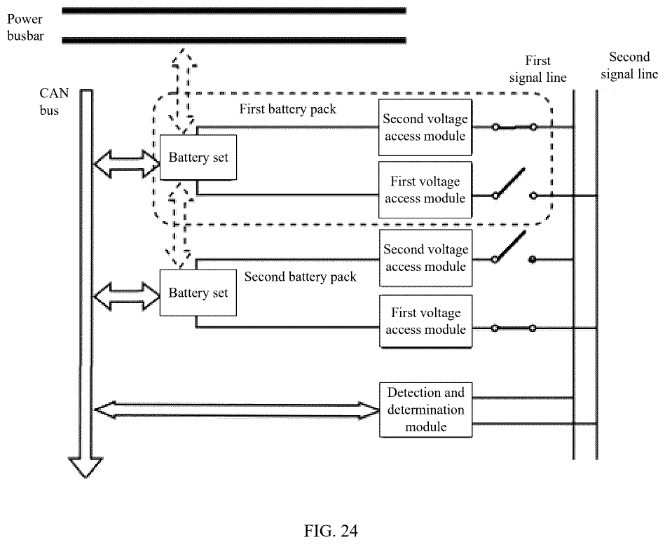

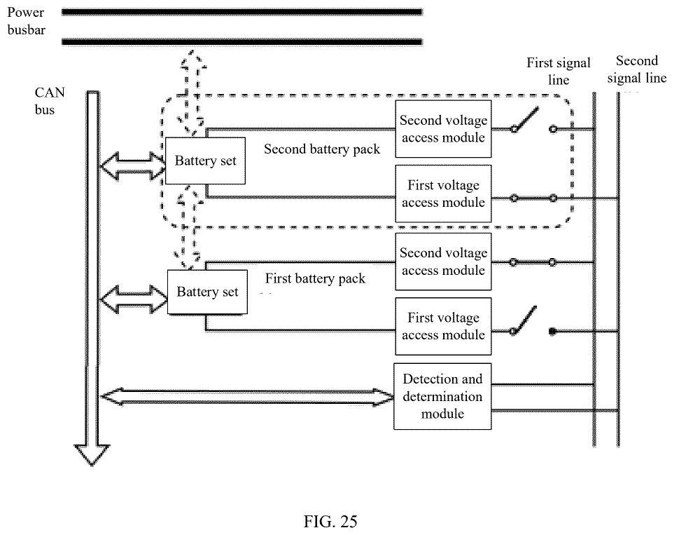

In this possible embodiment, compared with the aforementioned embodiments, a connection mode of each module in the battery pack and two terminals of the battery pack is different. As shown in FIG. 24 and FIG. 25, the first battery pack and the second battery pack marked in FIG. 24 and FIG. 25 are described as examples.

As shown in FIG. 24, when the positive terminal of the first battery pack is connected with the first signal line and the negative terminal of the second battery pack is connected with the second signal line, if the measured voltage value is a negative value, the positive terminal of the second battery pack is directly or indirectly connected with the negative terminal of the first battery pack, that is, the second battery pack is connected with the negative terminal side (the first input module) of the first battery pack. Further, if the measured voltage value is a negative value, and an absolute value of the voltage value is N times or close to N (N is a number greater than or equal to 2) times the voltage of a single battery pack, the positive terminal of the second battery pack is connected with the negative terminal of the first battery pack, that is, the second battery pack is connected with the negative terminal side (the first input module) of the first battery pack, and a total number of battery packs and/or battery pack sets connected in series between the positive terminal of the second battery pack and the negative terminal of the first battery pack are (N−2).

As shown in FIG. 25, when the positive terminal of the first battery pack is connected with the first signal line, and the negative terminal of the second battery pack is connected with the second signal line, if the measured voltage value is zero or close to zero, it can be determined that the second battery pack is connected with the first battery pack in series, and the negative terminal of the second battery pack is directly connected with the positive terminal of the first battery pack, that is, the second battery pack is directly connected with the positive terminal side (the second input module side) of the first battery pack, and no other battery packs or battery pack sets are connected in series between the second battery pack and the first battery pack. If the measured voltage value is a positive value, and the voltage value is M times or close to M (M is a number greater than or equal to 1) times the voltage of a single battery pack, it can be determined that the second battery pack is connected in series with the first battery pack, the negative terminal of the second battery pack is connected with the positive terminal of the first battery pack, that is, the second battery pack is connected with the positive terminal side (the second input module side) of the first battery pack, and a total number of battery packs and/or battery pack sets connected in series between the negative terminal of the second battery pack and the positive terminal of the first battery pack are M.

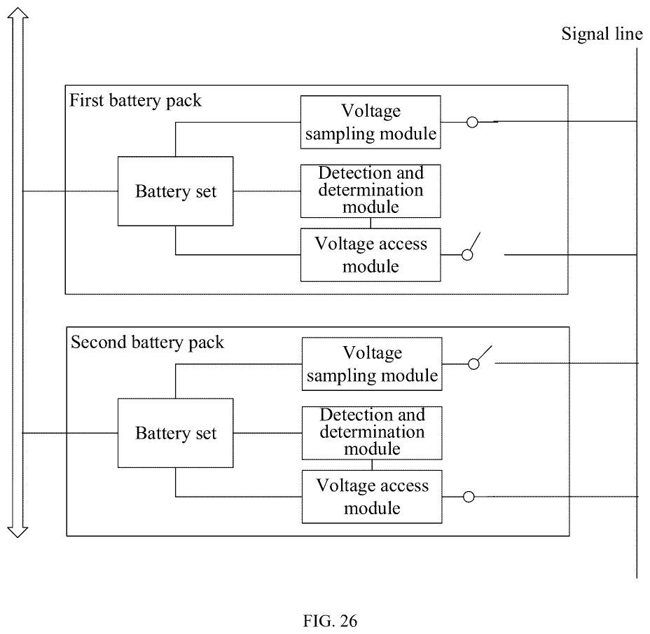

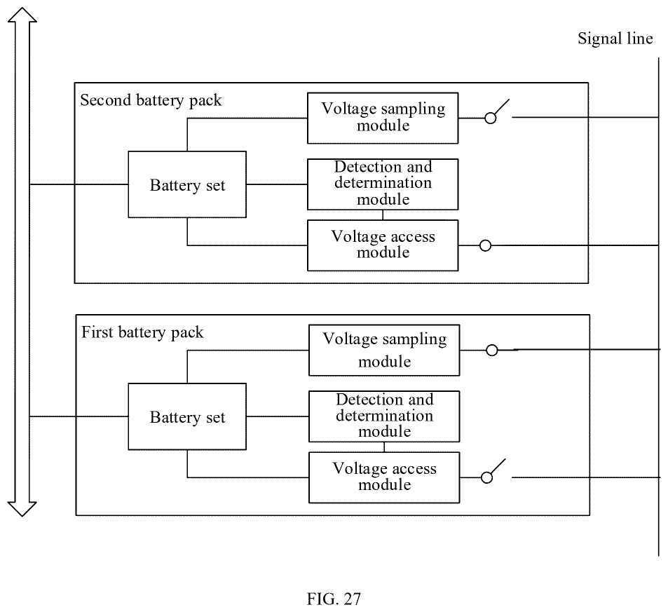

In some other implementations, the first battery pack and the second battery pack marked in FIG. 26 and FIG. 27 are described as examples.

When the positive terminal of the battery set of the first battery pack is connected with the signal line through the voltage sampling module, and the negative terminal of the battery set of the second battery pack is connected with the signal line through the voltage access module. As shown in FIG. 26, if the measured voltage value of the first battery pack is a negative value, it can be determined that the positive terminal of the battery set of the second battery pack is directly or indirectly connected with the negative terminal of the battery set of the first battery pack, that is, the second battery pack is connected with the negative terminal side (the voltage access module side) of the battery set of the first battery pack. Further, if the measured voltage value of the first battery pack is a negative value, and an absolute value of the voltage value is N times or close to N (N is a number greater than or equal to 2) times the voltage of a single battery pack, the positive terminal of the battery set of the second battery pack is connected with the negative terminal side (the voltage access module side) of the battery set of the first battery pack, and a total number of battery packs and/or battery pack sets are connected in series between the positive terminal of the battery set of the second battery pack and the negative terminal of the battery set of the first battery pack are (N−2).

When the positive terminal of the battery set of the first battery pack is connected with the signal line through the voltage sampling module, and the negative terminal of the battery set of the second battery pack is connected with the signal line through the voltage access module. As shown in FIG. 27, if the measured voltage value of the first battery pack is zero or close to zero, it can be determined that the second battery pack is connected with the first battery pack in series, and the negative terminal of the second battery pack is directly connected with the positive terminal of the first battery pack, that is, the second battery pack directly is connected with the positive terminal side (the voltage sampling module side) of the first battery pack, and no other battery packs or battery pack sets are connected in series between the second battery pack and the first battery pack. If the measured voltage value of the first battery pack is a positive value and the voltage value is M times or close to M (M is a number greater than or equal to 1) times the voltage of a single battery pack, it can be determined that the second battery pack is connected in series with the first battery pack, and the negative terminal of the second battery pack is connected with the positive terminal of the first battery pack, that is, the second battery pack is connected with the positive terminal side (the voltage sampling module side) of the first battery pack, and a total number of battery packs and/or battery pack sets connected in series between the negative terminal of the second battery pack and the positive terminal of the first battery pack are M.

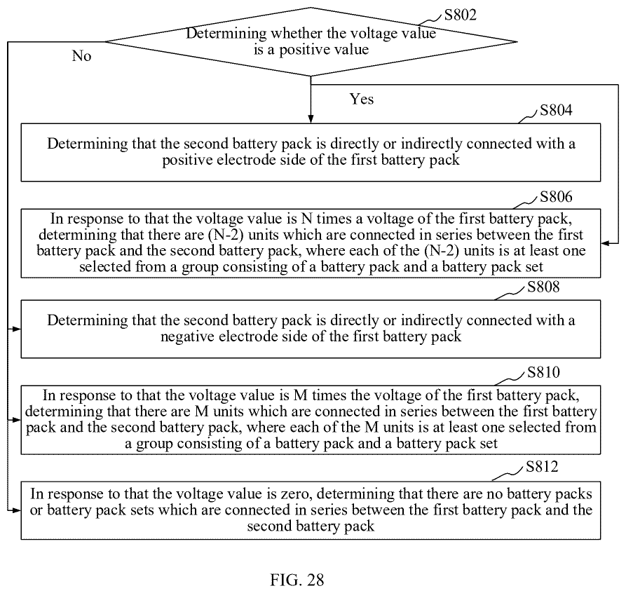

In another implementation, as shown in FIG. 28, if the positive terminals of the first battery pack and the second battery pack are controllably connected with the signal line through their own voltage access modules, respectively, and the negative terminals of the first battery pack and the second battery pack are controllably connected with the signal line through their own voltage sampling modules, respectively, the determining a connection state between the first battery pack and the second battery pack according to the voltage value includes at least one of the following:
S802: Determining whether the voltage value is a positive value.
S804: In response to that the voltage value is a positive value, determining that the second battery pack is directly or indirectly connected with a positive terminal side of the first battery pack.
S806: In response to the voltage value is a positive value and the voltage value is N times a voltage of the first battery pack, determining that there are (N−2) units which are connected in series between the first battery pack and the second battery pack, where each of the (N−2) units is at least one selected from a group consisting of a battery pack and a battery pack set.
S808: In response to that the voltage value is a negative value or zero, determining that the second battery pack is directly or indirectly connected with the negative terminal side of the first battery pack.
S810: In response to that the voltage value is a negative value and an absolute value of the voltage value is M times the voltage of the first battery pack, determining that there are M units which are connected in series between the first battery pack and the second battery pack, where each of the M units is at least one selected from a group consisting of a battery pack and a battery pack set.
S812: In response to that the voltage value is zero, determining that there are no battery packs or battery pack sets which are connected in series between the first battery pack and the second battery pack, where N is a number greater than or equal to 2, M is a number greater than or equal to 1, and the battery pack set includes a plurality of battery packs connected in parallel.

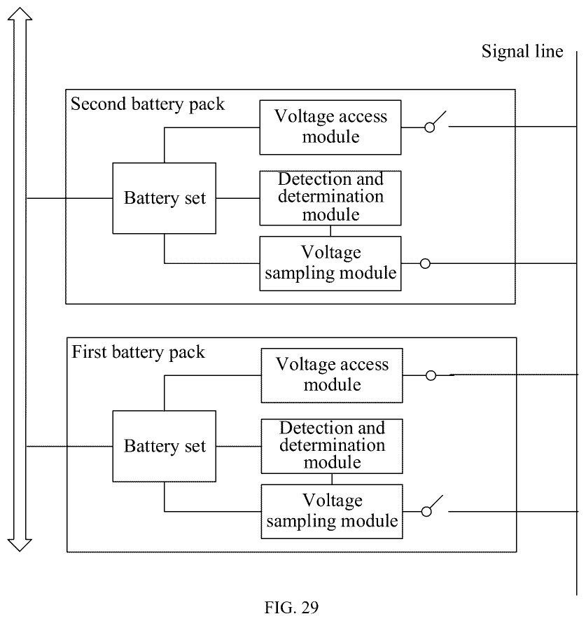

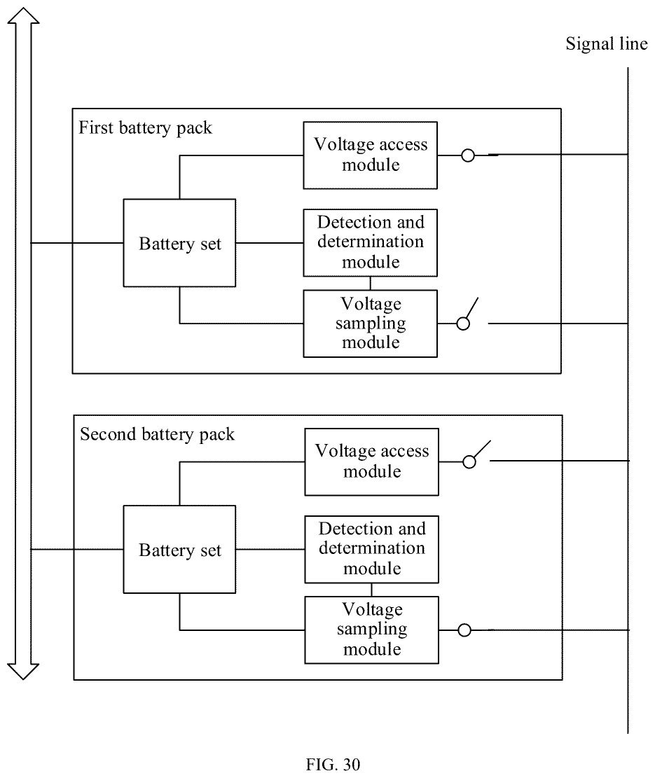

In some implementations, the first battery pack and the second battery pack marked in FIG. 29 and FIG. 30 are described as examples.

When the positive terminal of the first battery pack is connected with the signal line through the voltage access module, and the negative terminal of the second battery pack is connected with the signal line through the voltage sampling module, as shown in FIG. 29, at this time, the voltage sampling module in the second battery pack can measure the voltage value of the signal line. If the voltage value measured by the voltage sampling module in the second battery pack is a positive value, it can be determined that the negative terminal of the second battery pack is connected with the positive terminal of the first battery pack, that is, the second battery pack is connected with the positive terminal side (the voltage access module side) of the first battery pack. If the voltage value measured by the voltage sampling module in the second battery pack is N times or close to N (N is a number greater than or equal to 2) times the voltage of a single battery pack, it can be determined that the first battery pack is connected in series with the second battery pack, the negative terminal of the second battery pack is connected with the positive terminal of the first battery pack, and a total number of battery packs and/or battery pack sets connected in series between the negative terminal of the second battery pack and the positive terminal of the first battery pack are (N−2).

When the positive terminal of the first battery pack is connected with the signal line through the voltage access module, and the negative terminal of the second battery pack is connected with the signal line through the voltage sampling module. As shown in FIG. 30, if a voltage value measured by the voltage sampling module of the second battery pack is zero, it can be determined that the positive terminal of the second battery pack is directly connected with the negative terminal of the first battery pack, that is, the second battery pack directly is connected with the negative terminal side (a voltage sampling module side) of the first battery pack. No other battery packs or battery pack sets are connected in series between the second battery pack and the first battery pack. If the voltage value measured by the voltage sampling module of the second battery pack is a negative value, it can be determined that the second battery pack is connected in series with the first battery pack, and the positive terminal of the second battery pack is connected with the negative terminal of the first battery pack, that is, the second battery pack is connected with the negative terminal side (a voltage sampling module side) of the first battery pack. If the measured voltage value of the second battery pack is a negative value, and an absolute value of the voltage value is M times or close to M (M is a number greater than or equal to 1) times the voltage of a single battery pack, it can be determined that the second battery pack is connected in series with the first battery pack, the positive terminal of the second battery pack is connected with the negative terminal of the first battery pack, that is, the second battery pack is connected with the negative terminal side (a voltage sampling module side) of the first battery pack, and a total number of battery packs and/or battery pack sets connected in series between the negative terminal of the second battery pack and the positive terminal of the first battery pack are M.

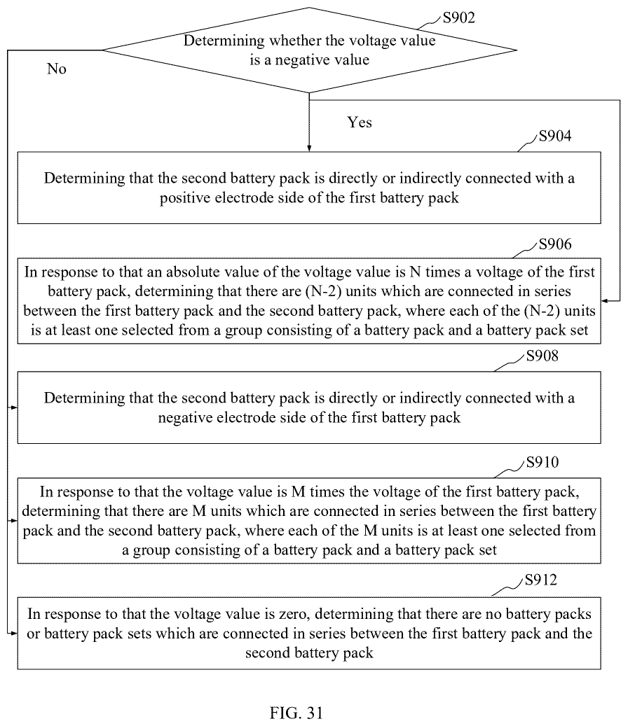

In another implementation, as shown in FIG. 31, if negative terminals of the first battery pack and the second battery pack are controllably connected with the signal line through their own voltage access modules, respectively, and positive terminals of the first battery pack and the second battery pack are controllably connected with the signal line through their own voltage sampling modules, respectively, the determining, a connection state between the first battery pack and the second battery pack according to the voltage value includes at least one of the following:
S902: Determining whether the voltage value is a negative value.
S904: In response to that the voltage value is a negative value, determining that the second battery pack is directly or indirectly connected with a positive terminal side of the first battery pack.
S906: In response to that the voltage value is a negative value and an absolute value of the voltage value being N times a voltage of the first battery pack, determining that there are (N−2) units which are connected in series between the first battery pack and the second battery pack, where each of the (N−2) units is at least one selected from a group consisting of a battery pack and a battery pack set.
S908: In response to that the voltage value is a positive value or zero, determining that the second battery pack is directly or indirectly connected with the negative terminal side of the first battery pack.
S910: In response to that the voltage value is a positive value and the voltage value is M times the voltage of the first battery pack, determining that there are M units which are connected in series between the first battery pack and the second battery pack, where each of the M units is at least one selected from a group consisting of a battery pack and a battery pack set.
S912: In response to that the voltage value is zero, determining that there are no battery packs or battery pack sets which are connected in series between the first battery pack and the second battery pack, where N is a number greater than or equal to 2, M is a number greater than or equal to 1, and the battery pack set includes a plurality of battery packs connected in parallel.

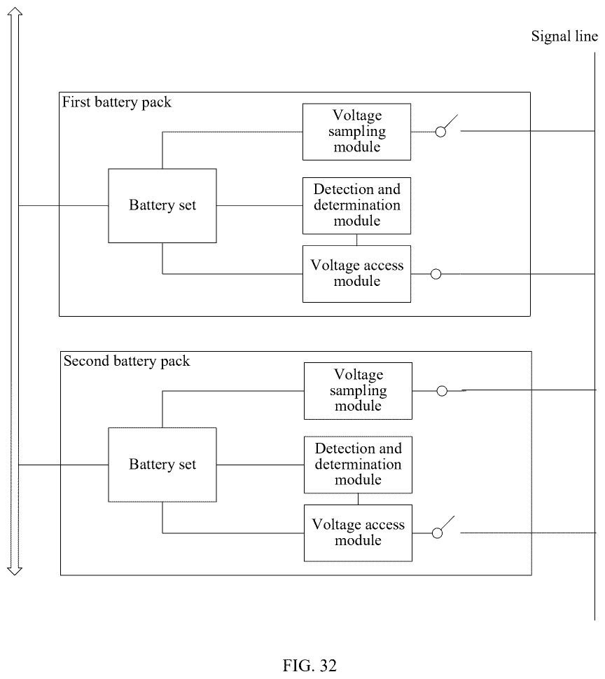

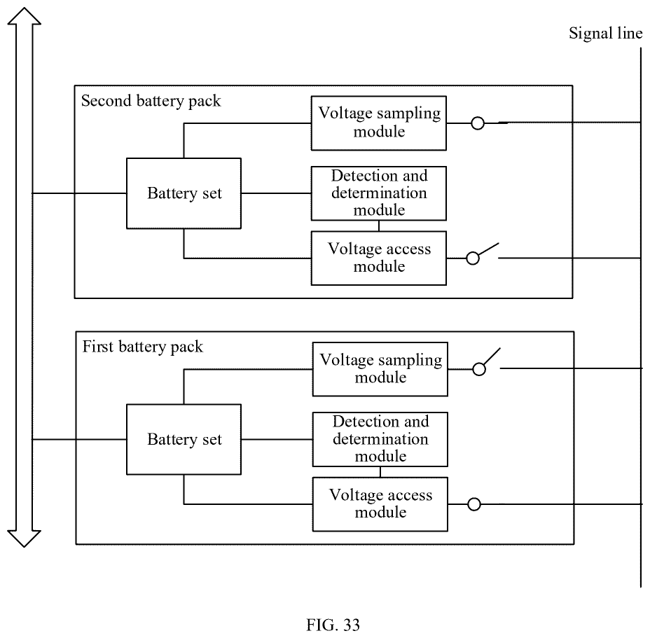

Specifically, the first battery pack and the second battery pack marked in FIG. 32 and FIG. 33 are described as examples.

As shown in FIG. 32, when a negative terminal of the first battery pack is connected with the signal line through the voltage access module, and a positive terminal of the second battery pack is connected with the signal line through the voltage sampling module, at this time, the voltage sampling module in the second battery pack can measure a voltage value of the signal line. If the voltage value measured by the voltage sampling module in the second battery pack is zero, it can be determined that the positive terminal of the second battery pack is directly connected with the negative terminal of the first battery pack, that is, the second battery pack is connected with a negative terminal side (a voltage access module side) of the first battery pack. If the voltage value measured by the voltage sampling module in the second battery pack is a positive value, and an absolute value of the voltage value is M times or close to M (M is a number greater than or equal to 1) times a voltage of a single battery pack, it can be determined that the second battery pack is connected in series with the first battery pack, the positive terminal of the second battery pack is connected with the negative terminal of the first battery pack, that is, the second battery pack is connected with the negative terminal side (the voltage access module side) of the first battery pack, and M battery packs and/or battery pack sets are connected in series between the negative terminal of the second battery pack and the positive terminal of the first battery pack are.

As shown in FIG. 33, when the negative terminal of the first battery pack is connected with the signal line through the voltage access module, and the positive terminal of the second battery pack is connected with the signal line through the voltage sampling module, at this time, the voltage sampling module in the second battery pack can measure the voltage value of the signal line. If the voltage value measured by the voltage sampling module in the second battery pack is a negative value, it can be determined that a negative terminal of the second battery pack is connected with a positive terminal of the first battery pack, that is, the second battery pack is connected with the positive terminal side (the voltage sampling module side) of the first battery pack. If the voltage value measured by the voltage sampling module in the second battery pack is a negative value, and an absolute value of the voltage value is N times or close to N (N is a number greater than or equal to 2) times a voltage of a single battery pack, it can be determined that the first battery pack is connected in series with the second battery pack, the negative terminal of the second battery pack is connected with the positive terminal of the first battery pack, and (N−2) battery packs and/or battery pack sets are connected in series between the negative terminal of the second battery pack and the positive terminal of the first battery pack.

Similarly, in this implementation, it should be noted that the aforementioned series connection of the total number of (N−2) battery packs and/or battery pack sets, or the series connection of the total number of M battery packs and/or battery pack sets refer to that other battery packs are connected in series between the first battery pack and the second battery pack, and since a voltage of a plurality of battery packs connected in parallel is equal to a voltage of a single battery pack, only the number of battery units connected in series can be determined according to a voltage value. The battery unit may be a single battery pack or a battery pack set composed of a plurality of battery packs connected in parallel. The number of the battery packs in the battery pack set cannot be determined only according to the voltage value of the signal line currently acquired. After identifying all the battery packs in sequence, the connection mode and number of all the battery packs in the entire battery system can be completely determined.

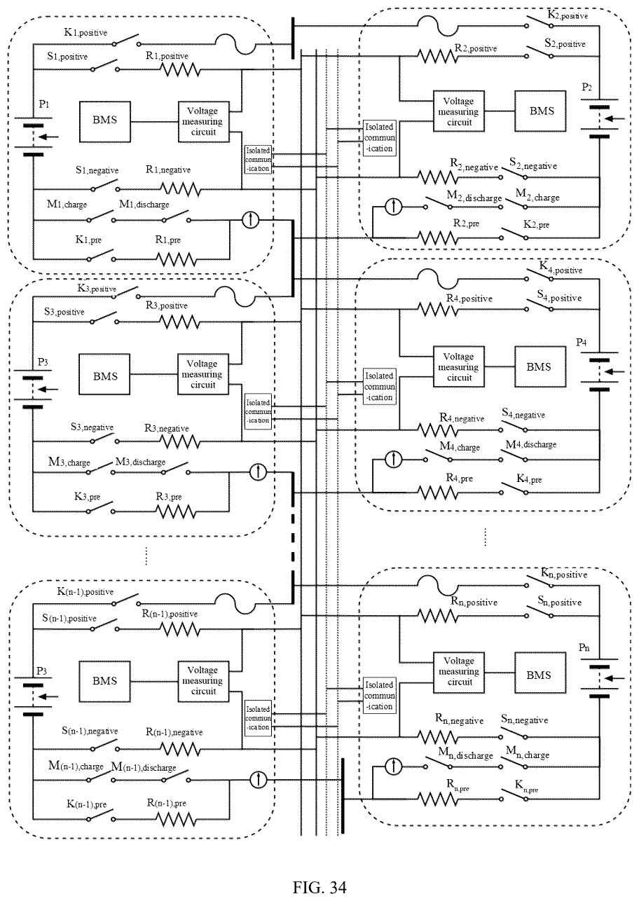

In some exemplary embodiments, as shown in FIG. 34, a circuit of battery packs which are connected both in series and parallel is most complicated. Therefore, a case where both series connection and parallel connection exist, i.e., a hybrid connection situation including a series and parallel connection is described as an example. A hybrid connection refers to a special battery system composed of battery packs connected in series and battery packs connected in parallel. P₁, P₂ . . . Pₙ₋₁, Pₙ in the figure represent battery packs, and two dashed lines connected with an isolated communication module are communication lines, such as a CAN bus. All the battery packs can communicate with each other through the isolated communication module. Two thin solid lines connected with a voltage access module (composed of a switch and a resistor of each battery pack) are signal lines. Two thick solid wires connected with a fuse are a power busbar. Taking the P₁ battery pack as an example, a BMS is a battery management system configured to acquire various parameters of a battery set of a battery pack from a current sensor and a voltage detection unit (not shown in the figures) and perform corresponding control. M_{1,charge} and M_{1,discharge} are charging and discharging circuit units of the battery pack, which controls charging and discharging of the battery pack according to a control signal of the BMS. K_{1,pre} and R_{1,pre} form a pre-charging unit of the battery pack, and is configured to buffer large current surges in a power-on process, where the pre-charging unit is connected in parallel with the charging and discharging circuit unit and then connected with the power busbar. K_{1,positive} is disposed between the fuse and the battery set of the P₁ battery pack as a general circuit control switch and configured to connect to the power busbar. S_{1,positive} and R_{1,positive} form a first voltage access module of the battery pack, which is configured to controllably connect with a positive terminal of the battery set to the first signal line. S_{1,negative} and R_{1,negative} form a second voltage access module of the battery pack, which is configured to controllably connect a negative terminal of the battery set to the second signal line. An isolated communication unit is connected with the communication bus (two dashed lines in the figure) so as to establish communication connection with other battery packs through the communication bus. A voltage measuring circuit and the BMS form a detection and determination module of the battery pack. The voltage measuring circuit is configured to measure a voltage value between the first signal line and the second signal line, and the BMS is configured to determine a connection state of the battery pack according to the voltage value. Structures of other battery packs are completely the same as a structure of the battery pack P₁ except that connection modes among the battery packs are different, which is not repeated here.

When identifying the connection state of the battery pack, a control host in the battery system can be determined first through a step of competing for a host and a slave. The determination method of the control host can refer to the aforementioned embodiment and will not be repeated here. In this embodiment, the battery pack P₃ is served as a control host, and the remaining battery packs are used as slaves. The control host can be equivalent to the first battery pack mentioned above, and each slave can be equivalent to the second battery pack or the third battery pack mentioned above. It should be noted that this embodiment is only described as a possible implementation, the purpose of which is to further explain the technical solution of the present disclosure, but not constituting a limitation on an actual scope of protection of the present disclosure.

Specifically, the battery pack P₃ served as the control host firstly controls S_{3.negative} to be turned off to connect a negative terminal of the battery pack P₃ to the second signal line, and sends information to the battery pack P₁ through the communication bus to make the battery pack P₁ control the S_{1,positive} to be turned off. The battery pack P₃ measures a voltage value between the first signal line and the second signal line through its own voltage measuring circuit. At this time, due to a series connection relationship of the battery pack P₁ and the battery pack P₃, and a direct connection between a negative terminal of the battery pack P₁ and a positive terminal of the battery pack P₃, the voltage value measured at this time is approximately twice a voltage value of the battery pack P₃, a specific multiple can be determined by dividing the measured voltage value by the voltage value of the battery pack P₃ and then performing rounding to obtain an integer. According to the measured voltage value, the battery pack P₃ can determine that the battery pack P₁ is connected in series with the battery pack P₃ and is directly connected in series at a positive terminal (a first voltage access module) thereof.

Further, the battery pack P₃ controls the S_{1,positive} to be turned off through the battery pack P₁ and controls the battery pack P₂ through the communication bus to control S_{2,positive} to be turned off. The battery pack P₃ measures the voltage value between the first signal line and the second signal line through its own voltage measuring circuit. At this time, the measured voltage value is also approximately twice the voltage value of the battery pack P₃. Therefore, the battery pack P₃ can determine that the battery pack P₂ is connected in series with the battery pack P₃ and is directly connected in series at a positive terminal (a first voltage access module) of the battery pack P₃. At the same time, the battery pack P₃ can also determine that the battery pack P₁ and the battery pack P₂ are connected in parallel.

Further, the battery pack P₃ controls the battery pack P₂ through the communication bus to control the S_{2,positive} to be turned on, and controls the battery pack P₄ through the communication bus to control S_{4,positive} to be turned off. The battery pack P₃ measures the voltage value through the voltage measuring circuit, at this time, the voltage value is approximately once the voltage value of the battery pack P₃. Therefore, the battery pack P₃ can determine that the battery pack P₄ is connected in parallel with the battery pack P₃.

Further, the battery pack P₃ controls the battery pack P₄ through the communication bus to control the S_{4,positive} to be turned on, and controls the battery pack P₅ through the communication bus to control S_{5,positive} to be turned off. The battery pack P₃ measures the voltage value through the voltage measuring circuit. At this time, the voltage value is about 0, and the battery pack P₃ can determine that the battery pack P₅ is connected in series with the battery pack P₃ and is directly connected in series at a negative terminal (a second voltage access module) of the battery pack P₃.

By analogy, this process is repeated until the battery pack P₃ series-parallel connection relationship between all the slave battery packs and the battery pack P₃ are determined, and the series-parallel connection relationship of the battery pack P and a total capacity and a total voltage of the battery pack P can be calculated.

Through the above-mentioned manner, it is possible to automatically identify the connection state among all the battery packs without any other operation after the user connects the battery packs arbitrarily, and further connection structures among all the battery packs in the entire battery system, thereby managing the battery system accurately.

It should be noted that considering that there may be losses or voltage differences that cannot be ignored between battery packs during current transmission in a practical application process, the measured voltage value or an absolute value of the voltage value may not necessarily be exactly equal to an integer multiple of a voltage of a battery pack. Therefore, in general, N and M can be integer values obtained by dividing the measured voltage value by the voltage value of a single battery pack and then performing rounding so as to determine a specific multiple (i.e., N times, M times, or zero as mentioned above). For example, for a battery pack with a voltage of 12 V, if the voltage value measured by the detection and determination module or the voltage sampling module is 32.5 V, then 32.5/12≈2.708 is calculated, which is then rounded to be determined as 3 times a battery pack voltage. If the voltage value measured by the detection and determination module or the voltage sampling module is 1.5 V, then 1.5/12≈0.125 is calculated, which is then rounded to determine the voltage value as zero. If the voltage value measured by the detection and determination module or the voltage sampling module is −7.5 V, an absolute value is taken first, then 7.5/12˜0.625 is calculated, which is then rounded to be determined as 1 times the battery pack voltage. By analogy, it can help to more accurately determine the measured voltage value of the signal line.

In this embodiment, after determining that the first battery pack and the second battery pack are in a series connection state, the relative position relationship between the first battery pack and the second battery pack, as well as the second battery pack connected to a positive terminal side or a negative terminal side of the first battery pack, and the number of the battery packs connected in series between the first battery pack and the second battery pack can be further determined according to the voltage value. Therefore, the connection structure in the first battery pack and the second battery pack can be better determined, and the total voltage and the total capacity of the battery pack acquired after series connection and/or parallel connection can be conveniently calculated subsequently.

In an embodiment, a battery management system is further provided, including: a memory and a processor, where the memory stores computer programs, and the processor implements steps in the above method embodiments when executing the computer program.

In an embodiment, a computer-readable storage medium is further provided, which stores computer programs. When the computer program is executed by a processor, the steps in the above method embodiments are implemented.

In an embodiment, a computer program product is further provided, including computer programs, where the computer program, when executed by a processor, implements steps in the above method embodiments.

The sequences of the above mentioned embodiments of the present disclosure are only for description and do not represent the advantages and disadvantages of the embodiments.

It should be understood that although the various steps in the flowcharts involved in the embodiments described above are displayed in the order indicated by the arrows, these steps are not necessarily executed in the order indicated by the arrows. Unless otherwise explicitly specified in the present disclosure, the execution sequence of these steps is not strictly limited, and these steps may be performed in other sequences. Moreover, at least part of the steps in the flowcharts involved in the embodiments described above may include a plurality of steps or a plurality of stages. These steps or stages are not necessarily executed at the same time, but can be executed at different times. The order of execution of these steps or stages is not necessarily performed sequentially, but may be performed in turn or alternately with other steps or at least a part of steps or stages in other steps.

In the present disclosure, in general, the same or similar term concepts, technical solutions, and/or application scenario descriptions are only described in detail when they first appear. When they appear again later, for the sake of simplicity, they are generally not repeated. When understanding the technical solutions and other contents of the present disclosure, the same or similar term concepts, technical solutions, and/or application scenario descriptions that are not described in detail later, reference can be referred to previous relevant detailed descriptions.

In the present disclosure, the description of each embodiment has its own emphasis. For parts that are not detailed or recorded in a certain embodiment, please refer to relevant descriptions in other embodiments.

Various technical features in the technical solution of the present disclosure may be combined arbitrarily. To simplify the description, not all possible combinations of the various technical features in the foregoing embodiments are described. However, as long as no conflict exists among the combinations of these technical features, they should be regarded as falling within the scope of the present disclosure.

According to the descriptions in the above implementations, those skilled in the art can clearly understand that the method according to the above embodiment may be implemented by means of software and an essential common hardware platform, or, of course, by means of hardware, however, in many cases, the former is a more preferable implementation. Based on this understanding, the technical solution of the present disclosure essentially, or the part contributing to the prior art, can be presented in the form of a software product. The computer software product is stored in an above mentioned storage medium (for example, a ROM/RAM, a magnetic disk, or an optical disc), and includes several instructions to enable a terminal device (which may be an electric device or a network device or the like) to execute the methods described in various embodiments of the present disclosure.

The above-described embodiments only describe several implementations of the present disclosure, and the description thereof is specific and detailed, but cannot therefore be understood as a limitation on the scope of the present disclosure. It should be noted that those skilled in the art can further make various variations and improvements without departing from the concept of the present disclosure, all of which fall within the protection scope of the present disclosure. Therefore, the protection scope of the present disclosure shall be subject to the appended claims.

1. A battery system, comprising:
a plurality of battery packs, the plurality of battery packs being directly or indirectly connected;
a signal line, the signal line being in controllable connection with each of the plurality of battery packs; and
a detection and determination module, configured to acquire a voltage value of the signal line, and determine, according to the voltage value, at least one selected from a group consisting of a connection mode between the plurality of battery packs and a relative position between the plurality of battery packs.

2. The battery system according to claim 1, wherein the battery pack comprises a battery set, a first voltage access module, and a second voltage access module;
the signal line comprises at least one first signal line and at least one second signal line;
a positive terminal of the battery set is in controllable connection with the first signal line via the first voltage access module; and
a negative terminal of the battery set is in controllable connection with the second signal line via the second voltage access module.

3. The battery system according to claim 2, wherein the battery pack comprises a voltage dividing module connected in series with the battery set;
the positive terminal of the battery set is in controllable connection with the first signal line via the voltage dividing module and the first voltage access module; and
the negative terminal of the battery set is in controllable connection with the second signal line via the second voltage access module.

4. (canceled)

5. The battery system according to claim 2, wherein
the detection and determination module is disposed in at least one first battery pack of the plurality of battery packs;
the detection and determination module is configured to control a first voltage access module of the first battery pack to connect with the first signal line;
the detection and determination module is configured to communicate with at least one second battery pack of the plurality of battery packs, so that the second battery pack controls a second voltage access module of the second battery pack to connect with the second signal line; and
the detection and determination module is configured to acquire a voltage value between the first signal line and the second signal line, and determine, according to the voltage value, at least one selected from a group consisting of a connection mode between the first battery pack and the second battery pack and a relative position between the first battery pack and the second battery pack.

6. The battery system according to claim 2, wherein
the detection and determination module is disposed in at least one first battery pack of the plurality of battery packs;
the detection and determination module is configured to control a second voltage access module of the first battery pack to connect with the second signal line;
the detection and determination module is configured to communicate with at least one second battery pack of the plurality of battery packs, so that the second battery pack controls a first voltage access module of the second battery pack to connect with the first signal line; and
the detection and determination module is configured to acquire a voltage value between the first signal line and the second signal line, and determine, according to the voltage value, at least one selected from a group consisting of a connection mode between the first battery pack and the second battery pack, and a relative position between the first battery pack and the second battery pack.

7. The battery system according to claim 2, wherein
the detection and determination module is disposed as an independent module in the battery system;
the detection and determination module is configured to communicate with at least one first battery pack and at least one second battery pack of the plurality of battery packs, so that the first battery pack controls a first voltage access module of the first battery pack to connect with the first signal line and the second battery pack controls a second voltage access module of the second battery pack to connect with the second signal line; and
the detection and determination module is configured to acquire a voltage value between the first signal line and the second signal line, and determine, according to the voltage value, at least one selected from a group consisting of a connection mode between the first battery pack and the second battery pack and a relative position between relative position between the first battery pack and the second battery pack.

8. The battery system according to claim 2, wherein
the detection and determination module is disposed as an independent module in the battery system;
the detection and determination module is configured to communicate with at least one first battery pack and at least one second battery pack of the plurality of battery packs, so that the first battery pack controls a second voltage access module of the first battery pack to connect with the second signal line and the second battery pack controls a first voltage access module of the second battery pack to connect with the first signal line; and
the detection and determination module is configured to acquire a voltage value between the first signal line and the second signal line, and determine, according to the voltage value, at least one selected from a group consisting of a connection mode between the first battery pack and the second battery pack and a relative position between the first battery pack and the second battery pack.

9. The battery system according to claim 1, wherein
the battery pack comprises a battery set, a voltage access module, and a voltage sampling module;
a positive terminal of the battery set is in controllable connection with the signal line via the voltage access module; and
a negative terminal of the battery set is in controllable connection with the signal line via the voltage sampling module.

10. The battery system according to claim 9, wherein
the detection and determination module is disposed in at least one first battery pack of the plurality of battery packs;
the detection and determination module is configured to control a voltage sampling module of the first battery pack to connect with the signal line;
the detection and determination module is configured to communicate with at least one second battery pack of the plurality of battery packs, so that the second battery pack controls a voltage access module of the second battery pack to connect with the signal line; and
the detection and determination module is configured to acquire a voltage value of the signal line measured by the voltage sampling module of the first battery pack, and determine, according to the voltage value, at least one selected from a group consisting of a connection mode between the first battery pack and the second battery pack and a relative position between the first battery pack and the second battery pack.

11. The battery system according to claim 9, wherein
the detection and determination module is disposed in at least one first battery pack of the plurality of battery packs;
the detection and determination module is configured to control a voltage access module of the first battery pack to connect with the signal line;
the detection and determination module is configured to communicate with at least one second battery pack of the plurality of battery packs, so that the second battery pack controls a voltage sampling module of the second battery pack to connect with the signal line; and
the detection and determination module is configured to acquire a voltage value of the signal line measured by the voltage sampling module of the second battery pack, and determine, according to the voltage value, at least one selected from a group consisting of a connection mode between the first battery pack and the second battery pack and a relative position between the first battery pack and the second battery pack.

12. A battery pack connection state identification method, wherein the method is applied to a first battery pack in a battery system composed of at least one first battery pack and at least one second battery pack, and the method comprises:
controlling the first battery pack and the second battery pack to connect with a signal line;
acquiring a voltage value of the signal line; and
determining, according to the voltage value, a connection state between the first battery pack and the second battery pack.

13. The method according to claim 12, wherein the first battery pack and the second battery pack are controllably connected with a first signal line via their own first voltage access modules, respectively, and controllably connected with a second signal line via their own second voltage access modules, respectively;
the controlling the first battery pack and the second battery pack to connect with a signal line comprises:
controlling a second voltage access module of the first battery pack to connect with the second signal line; and
sending first information to the second battery pack, the first information being used to instruct a first voltage access module of the second battery pack to connect with the first signal line; and
the acquiring a voltage value of the signal line comprises:
acquiring a voltage value between the first signal line and the second signal line.

14. The method according to claim 13, wherein the determining, according to the voltage value, a connection state between the first battery pack and the second battery pack comprises at least one of the following:
in response to that the voltage value is within a first preset range, determining that the first battery pack and the second battery pack are in a parallel connection state; and
in response to that the voltage value is not within the first preset range, determining that the first battery pack and the second battery pack are in a series connection state.

15. The method according to claim 14, wherein the determining that the first battery pack and the second battery pack are in a series connection state comprises:
determining, according to the voltage value, at least one selected from a group consisting of a relative position between the first battery pack and the second battery pack, and the number of battery packs connected in series.

16. The method according to claim 15, wherein in a case that a positive terminal of the first battery pack and a positive terminal of the second battery pack are controllably connected with the first signal line via their own first voltage access modules, respectively, and a negative terminal of the first battery pack and a negative terminal of the second battery pack are controllably connected with the second signal line via their own second voltage access modules, respectively, the determining, according to the voltage value, at least one selected from a group consisting of a relative position between the first battery pack and the second battery pack, and the number of battery packs connected in series comprises at least one of the following:
in response to that the voltage value is a positive value, determining that the second battery pack is directly or indirectly connected with a positive terminal side of the first battery pack;
in response to that the voltage value is a negative value or zero, determining that the second battery pack is directly or indirectly connected with a negative terminal side of the first battery pack;
in response to that the voltage value is a positive value and the voltage value is N times a voltage of the first battery pack, determining that there are (N−2) units which are connected in series between the first battery pack and the second battery pack, wherein each of the (N−2) units is at least one selected from a group consisting of a battery pack and a battery pack set;
in response to that the voltage value is a negative value and an absolute value of the voltage value is M times the voltage of the first battery pack, determining that there are M units which are connected in series between the first battery pack and the second battery pack, wherein each of the M units is at least one selected from a group consisting of a battery pack and a battery pack set;
in response to that the voltage value is zero, determining that there are no battery packs or battery pack sets which are connected in series between the first battery pack and the second battery pack;
wherein N is a number greater than or equal to 2, M is a number greater than or equal to 1, and the battery pack set comprises a plurality of battery packs connected in parallel; or,
in a case that the negative terminal of the first battery pack and the negative terminal of the second battery pack are controllably connected with the first signal line via their own first voltage access modules, respectively, and the positive terminal of the first battery pack and the positive terminal of the second battery pack are controllably connected with the second signal line via their own second voltage access modules, respectively, the determining, according to the voltage value, at least one selected from a group consisting of a relative position between the first battery pack and the second battery pack and the number of battery packs connected in series comprises at least one of the following:
in response to that the voltage value is a positive value or zero, determining that the second battery pack is directly or indirectly connected with the positive terminal side of the first battery pack;
in response to that the voltage value is a negative value, determining that the second battery pack is directly or indirectly connected with the negative terminal side of the first battery pack;
in response to that the voltage value is a positive value and the voltage value is M times the voltage of the first battery pack, determining that there are M units which are connected in series between the first battery pack and the second battery pack, wherein each of the M units is at least one selected from a group consisting of a battery pack and a battery pack set;
in response to that the voltage value is a negative value and an absolute value of the voltage value is N times the voltage of the first battery pack, determining that there are (N−2) units which are connected in series between the first battery pack and the second battery pack, and each of the M units is at least one selected from a group consisting of a battery pack and a battery pack set; and
in response to that the voltage value is zero, determining that there are no battery packs or battery pack sets which are connected in series between the first battery pack and the second battery pack;
wherein N is a number greater than or equal to 2, M is a number greater than or equal to 1, and the battery pack set comprises a plurality of battery packs connected in parallel.

17. The method according to claim 12, wherein the first battery pack and the second battery pack are controllably connected with the signal line via their own voltage access modules and voltage sampling modules, respectively;
the controlling the first battery pack and the second battery pack to connect with a signal line comprises:
controlling a voltage sampling module of the first battery pack to connect with the signal line; and
sending second information to the second battery pack, the second information being used to instruct a voltage access module of the second battery pack to connect with the signal line; and
the acquiring a voltage value of the signal line comprises:
acquiring a voltage value of the signal line measured by the voltage sampling module of the first battery pack.

18. The method according to claim 12, wherein the first battery pack and the second battery pack are controllably connected with the signal line via their own voltage access modules and voltage sampling modules, respectively;
the controlling the first battery pack and the second battery pack to connect with a signal line comprises:
controlling a voltage access module of the first battery pack to connect with the signal line; and
sending third information to the second battery pack, the third information being used to instruct a voltage sampling module of the second battery pack to connect with the signal line; and
the acquiring a voltage value of the signal line comprises:
acquiring a voltage value of the signal line measured by the voltage sampling module of the second battery pack.

19. The method according to claim 12, wherein the determining, according to the voltage value, a connection state between the first battery pack and the second battery pack comprises at least one of the following:
in response to that the voltage value is within a first preset range, determining that the first battery pack and the second battery pack are in a parallel connection state; and
in response to that the voltage value is not within the first preset range, determining that the first battery pack and the second battery pack are in a series connection state.

20. The method according to claim 17, wherein in a case that a positive terminal of the first battery pack and a positive terminal of the second battery pack are controllably connected with the signal line via their own voltage access modules, respectively, and a negative terminal of the first battery pack and a negative terminal of the second battery pack are controllably connected with the signal line via their own voltage sampling modules, respectively, the determining, according to the voltage value, a connection state between the first battery pack and the second battery pack comprises at least one of the following:
in response to that the voltage value is a positive value, determining that the second battery pack is directly or indirectly connected with a positive terminal side of the first battery pack;
in response to that the voltage value is a negative value or zero, determining that the second battery pack is directly or indirectly connected with a negative terminal side of the first battery pack;
in response to that the voltage value is a positive value and the voltage value is N times a voltage of the first battery pack, determining that there are (N−2) units which are connected in series between the first battery pack and the second battery pack, wherein each of the (N−2) units is at least one selected from a group consisting of a battery pack and a battery pack set; and
in response to that the voltage value is a negative value and an absolute value of the voltage value is M times the voltage of the first battery pack, determining that there are M units which are connected in series between the first battery pack and the second battery pack, wherein each of the M units is at least one selected from a group consisting of a battery pack and a battery pack set;
in response to that the voltage value is zero, determining that there are no battery packs or battery pack sets which are connected in series between the first battery pack and the second battery pack;
wherein N is a number greater than or equal to 2, M is a number greater than or equal to 1, and the battery pack set comprises a plurality of battery packs connected in parallel. or,
in a case that the negative terminal of the first battery pack and the negative terminal of the second battery pack are controllably connected with the first signal line via their own voltage access modules, respectively, the positive terminal of the first battery pack and the positive terminal of the second battery pack are controllably connected with the second signal line via their own voltage sampling modules, respectively, the determining, according to the voltage value, a connection state between the first battery pack and the second battery pack comprises at least one of the following:
in response to that the voltage value is a positive value or zero, determining that the second battery pack is directly or indirectly connected with the positive terminal side of the first battery pack;
in response to that the voltage value is a negative value, determining that the second battery pack is directly or indirectly connected with the negative terminal side of the first battery pack;
in response to that the voltage value is a positive value and the voltage value is M times the voltage of the first battery pack, determining that there are M units which are connected in series between the first battery pack and the second battery pack, wherein each of the M units is at least one selected from a group consisting of a battery pack and a battery pack set;
in response to that the voltage value is a negative value and an absolute value of the voltage value is N times the voltage of the first battery pack, determining that there are (N−2) units which are connected in series between the first battery pack and the second battery pack, wherein each of the (N−2) units is at least one selected from a group consisting of a battery pack and a battery pack set; and
in response to that the voltage value is zero, determining that there are no battery packs or battery pack sets which are connected in series between the first battery pack and the second battery pack;
wherein N is a number greater than or equal to 2, M is a number greater than or equal to 1, and the battery pack set comprises a plurality of battery packs connected in parallel.

21. The method according to claim 18, wherein in a case that a positive terminal of the first battery pack and a positive terminal of the second battery pack are controllably connected with the signal line via their own voltage access modules, respectively, and a negative terminal of the first battery pack and a negative terminal of the second battery pack are controllably connected with the signal line via their own voltage sampling modules, respectively, the determining, according to the voltage value, a connection state between the first battery pack and the second battery pack comprises at least one of the following:
in response to that the voltage value is a positive value, determining that the second battery pack is directly or indirectly connected with a negative terminal side of the first battery pack;
in response to that the voltage value is a negative value or zero, determining that the second battery pack is directly or indirectly connected with a positive terminal side of the first battery pack;
in response to that the voltage value is a positive value and the voltage value is N times a voltage of the first battery pack, determining that there are (N−2) units which are connected in series between the first battery pack and the second battery, wherein each of the (N−2) units is at least one selected from a group consisting of a battery pack and a battery pack set;
in response to that the voltage value is a negative value and an absolute value of the voltage value is M times the voltage of the first battery pack, determining that there are M units which are connected in series between the first battery pack and the second battery pack, wherein each of the M units is at least one selected from a group consisting of a battery pack and a battery pack set; and
in response to that the voltage value is zero, determining that there are no battery packs or battery pack sets which are connected in series between the first battery pack and the second battery pack;
wherein N is a number greater than or equal to 2, M is a number greater than or equal to 1, and the battery pack set comprises a plurality of battery packs connected in parallel; or,
in a case that the negative terminal of the first battery pack and the negative terminal of the second battery pack are controllably connected with the signal line via their own voltage access modules, respectively, and the positive terminal of the first battery pack and the positive terminal of the second battery pack are controllably connected with the signal line through their own voltage sampling modules, respectively, the determining, according to the voltage value, a connection state between the first battery pack and the second battery pack comprises at least one of the following:
in response to that the voltage value is a positive value or zero, determining that the second battery pack is directly or indirectly connected with the negative terminal side of the first battery pack;
in response to that the voltage value is a negative value, determining that the second battery pack is directly or indirectly connected with the positive terminal side of the first battery pack;
in response to that the voltage value is a positive value and the voltage value is M times the voltage of the first battery pack, determining that there are M units which are connected in series between the first battery pack and the second battery pack, wherein each of the M units is at least one selected from a group consisting of a battery pack and a battery pack set;
in response to that the voltage value is a negative value and an absolute value of the voltage value is N times the voltage of the first battery pack, determining that there are (N−2) units which are connected in series between the first battery pack and the second battery pack, wherein each of the (N−2) units is at least one selected from a group consisting of a battery pack and a battery pack set; and
in response to that the voltage value is zero, determining that there are no battery packs or battery pack sets which are connected in series between the first battery pack and the second battery pack;
wherein N is a number greater than or equal to 2, M is a number greater than or equal to 1, and the battery pack set comprises a plurality of battery packs connected in parallel.
